(19) United States
(12) Patent Application Publication
(10) Pub. No.: US 2025/0194332 A1
(43) Pub. Date: Jun. 12, 2025

(54) PHOTOELECTRIC CONVERSION ELEMENT AND PHOTODETECTOR

(71) Applicant: SONY SEMICONDUCTOR SOLUTIONS CORPORATION, KANAGAWA (JP)

(72) Inventors: RYOSUKE SUZUKI, KANAGAWA (JP); IWAO YAGI, KANAGAWA (JP); SHINTAROU HIRATA, KANAGAWA (JP); MASAHIRO JOEI, KANAGAWA (JP)

(21) Appl. No.: 18/844,451

(22) PCT Filed: Mar. 6, 2023
(86) PCT No.: PCT/JP2023/008332

§ 371 Date: Sep. 6, 2024

(30) Foreign Application Priority Data
Mar. 15, 2022 (JP) 2022-039791

(51) Int. Cl. H10K 39/32

(52) U.S. Cl. CPC H10K 39/32

(57) ABSTRACT

A photoelectric conversion element according to an embodiment of the present disclosure includes: a first electrode and a second electrode disposed side by side with each other; a third electrode disposed to be opposed to the first electrode and the second electrode; a photoelectric conversion layer provided between the first electrode and the third electrode and between the second electrode and the third electrode; and a semiconductor layer provided between the first electrode and the photoelectric conversion layer and between the second electrode and the photoelectric conversion layer, the semiconductor layer including a first layer and a second layer stacked in order from a side of the first electrode and the second electrode, the first layer having a thickness smaller than a thickness of the second layer, the thickness of the first layer being 3 nm or more and 5 nm or less.

### TECHNICAL FIELD

The present disclosure relates to a photoelectric conversion element using an organic material, for example, and a photodetector including the photoelectric conversion element.

### BACKGROUND ART

For example, PTL 1 discloses an imaging element including a photoelectric conversion section that includes a first electrode, a photoelectric conversion layer, and a second electrode which are stacked, in which a composite oxide layer including indium-gallium-zinc composite oxide (IGZO) is provided between the first electrode and the photoelectric conversion layer, thereby achieving an improvement in photoresponsivity.

### CITATION LIST

### Patent Literature

PTL 1: International Publication No. WO 2019/035252

### SUMMARY OF THE INVENTION

Incidentally, a photoelectric conversion element and a photodetector are required to have improved reliability.

It is desirable to provide a photoelectric conversion element and a photodetector that make it possible to improve reliability.

A photoelectric conversion element according to an embodiment of the present disclosure includes: a first electrode and a second electrode disposed side by side with each other; a third electrode disposed to be opposed to the first electrode and the second electrode; a photoelectric conversion layer provided between the first electrode and the third electrode and between the second electrode and the third electrode; and a semiconductor layer provided between the first electrode and the photoelectric conversion layer and between the second electrode and the photoelectric conversion layer, the semiconductor layer including a first layer and a second layer stacked in order from a side of the first electrode and the second electrode, the first layer having a thickness smaller than a thickness of the second layer, the thickness of the first layer being 3 nm or more and 5 nm or less.

A photodetector according to an embodiment of the present disclosure includes a plurality of pixels each including one or a plurality of photoelectric conversion elements, in which the photoelectric conversion element according to an embodiment of the present disclosure is provided as the photoelectric conversion element.

In the photoelectric conversion element and the photodetector according to the respective embodiments of the present disclosure, the semiconductor layer including the first layer and the second layer stacked in order from the side of the first electrode and the second electrode disposed side by side with each other, in which the first layer has a thickness that is smaller than a thickness of the second layer and that is 3 nm or more and 5 nm or less, is provided between the first electrode and the photoelectric conversion layer and between the second electrode and the photoelectric conversion layer. This reduces the influence of fixed electric charge on a surface of the semiconductor layer while maintaining carrier conduction in the semiconductor layer.

### BRIEF DESCRIPTION OF THE DRAWINGS

FIG. 1 is a schematic cross-sectional view of an example of a configuration of an imaging element according to an embodiment of the present disclosure.

FIG. 2 is a schematic plan view of an example of a pixel configuration of an imaging device including the imaging element illustrated in FIG. 1.

FIG. 3 is a schematic cross-sectional view of an example of a configuration of a photoelectric conversion section illustrated in FIG. 1.

FIG. 4 is a characteristic diagram illustrating a relationship between a delayed electric charge amount and a film thickness of a first layer of a semiconductor layer illustrated in FIG. 3.

FIG. 5 is a characteristic diagram illustrating a relationship between a drain current and the film thickness of the first layer of the semiconductor layer illustrated in FIG. 3.

FIG. 6 is a characteristic diagram illustrating a relationship between a variation amount of a threshold voltage and a film thickness of a second layer of the semiconductor layer illustrated in FIG. 3.

FIG. 7A is a characteristic diagram illustrating a simulation result of a relationship between a carrier concentration and a distance from an interface between an insulating layer and the semiconductor layer illustrated in FIG. 3.

FIG. 7B is an enlarged view of a portion of FIG. 7A.

FIG. 8 is an equivalent circuit diagram of the imaging element illustrated in FIG. 1.

FIG. 9 is a schematic view of an arrangement of transistors constituting a controller and a lower electrode of the imaging element illustrated in FIG. 1.

FIG. 10 is an explanatory cross-sectional view of a method of manufacturing the imaging element illustrated in FIG. 1.

FIG. 11 is a cross-sectional view of a step subsequent to FIG. 10.

FIG. 12 is a cross-sectional view of a step subsequent to FIG. 11.

FIG. 13 is a cross-sectional view of a step subsequent to FIG. 12.

FIG. 14 is a cross-sectional view of a step subsequent to FIG. 13.

FIG. 15 is a cross-sectional view of a step subsequent to FIG. 14.

FIG. 16 is a timing diagram illustrating an operation example of the imaging element illustrated in FIG. 1.

FIG. 17 is a schematic cross-sectional view of a configuration of a photoelectric conversion section according to Modification Example 1 of the present disclosure.

FIG. 18 is a schematic cross-sectional view of a configuration of a photoelectric conversion section according to Modification Example 2 of the present disclosure.

FIG. 19A is a schematic cross-sectional view of an example of a configuration of an imaging element according to Modification Example 3 of the present disclosure.

FIG. 19B is a schematic plan view of an example of a pixel configuration of an imaging device including the imaging element illustrated in FIG. 19A.

FIG. 20A is a schematic cross-sectional view of an example of a configuration of an imaging element according to Modification Example 4 of the present disclosure.

FIG. 20B is a schematic plan view of an example of a pixel configuration of an imaging device including the imaging element illustrated in FIG. 20A.

FIG. 21 is a schematic cross-sectional view of an example of a configuration of an imaging element according to Modification Example 5 of the present disclosure.

FIG. 22 is a block diagram illustrating a configuration of an imaging device using, as a pixel, the imaging element illustrated in FIG. 1 or other drawings.

FIG. 23 is a functional block diagram illustrating an example of an electronic apparatus (camera) using the imaging device illustrated in FIG. 22.

FIG. 24A is a schematic view of an example of an overall configuration of a photodetection system using the imaging device illustrated in FIG. 22.

FIG. 24B is a diagram illustrating an example of a circuit configuration of the photodetection system illustrated in FIG. 24A

FIG. 25 is a view depicting an example of a schematic configuration of an endoscopic surgery system.

FIG. 26 is a block diagram depicting an example of a functional configuration of a camera head and a camera control unit (CCU).

FIG. 27 is a block diagram depicting an example of schematic configuration of a vehicle control system.

FIG. 28 is a diagram of assistance in explaining an example of installation positions of an outside-vehicle information detecting section and an imaging section.

### MODES FOR CARRYING OUT THE INVENTION

In the following, description is given of embodiments of the present disclosure in detail with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. Embodiment (An example of an imaging element including, between a lower electrode and a photoelectric conversion layer, a semiconductor layer including two layers (a first layer and a second layer) having a predetermined film thickness ratio)
   1-1. Configuration of Imaging Element
   1-2. Method of Manufacturing Imaging Element
   1-3. Signal Acquisition Operation of Imaging Element
   1-4. Workings and Effects
2. Modification Examples
   2-1. Modification Example 1 (Another example of the configuration of the photoelectric conversion section)
   2-2. Modification Example 2 (Another example of the configuration of the photoelectric conversion section)
   2-3. Modification Example 3 (An example of an imaging element that uses a color filter to disperse light)
   2-4. Modification Example 4 (Another Example of the imaging element that uses a color filter to disperse light)
   2-5. Modification Example 5 (An example of an imaging element in which a plurality of photoelectric conversion sections is stacked)
3. Application Examples
4. Practical Application Examples

### 1. Embodiment

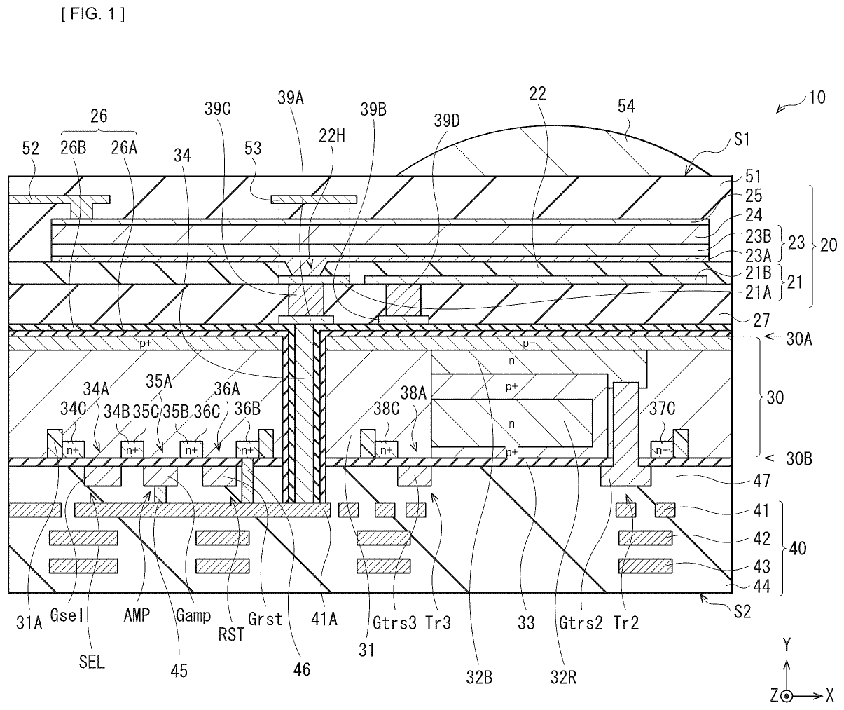

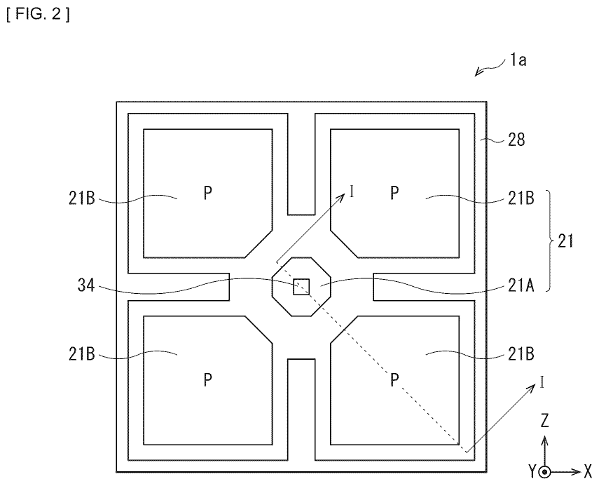

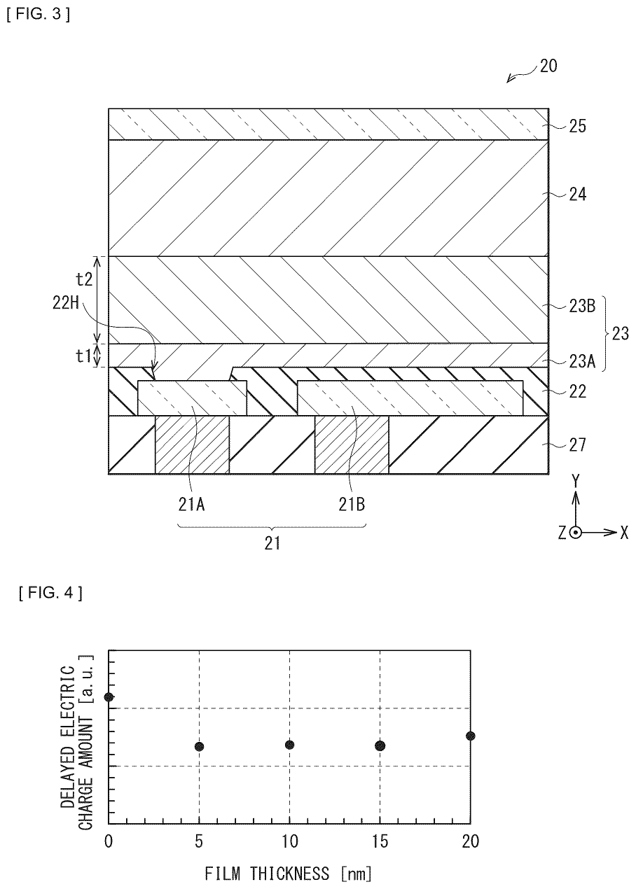

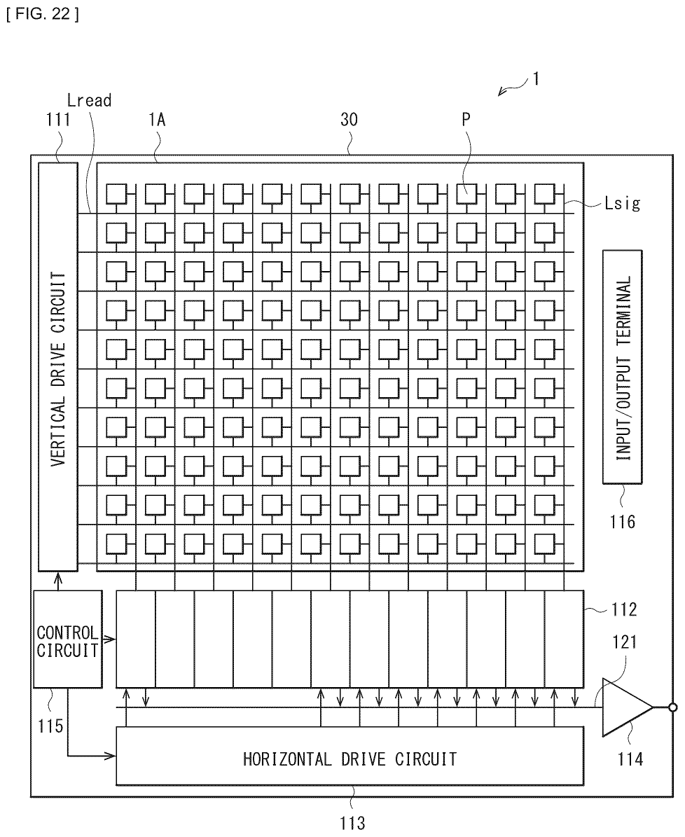

FIG. 1 illustrates a cross-sectional configuration of an imaging element (an imaging element 10) according to an embodiment of the present disclosure. FIG. 2 schematically illustrates an example of a planar configuration of the imaging element 10 illustrated in FIG. 1, and FIG. 1 illustrates a cross-section taken along a line I-I illustrated in FIG. 2. FIG. 3 schematically illustrates, in an enlarged manner, an example of a cross-sectional configuration of a main part (a photoelectric conversion section 20) of the imaging element 10 illustrated in FIG. 1. The imaging element 10 constitutes, for example, one pixel (a unit pixel P) repeatedly arranged in array in a pixel section 1A of an imaging device (e.g., an imaging device 1; see FIG. 22) such as a CMOS (Complementary Metal Oxide Semiconductor) image sensor used for an electronic apparatus such as a digital still camera or a video camera. In the pixel section 1A, as illustrated in FIG. 2, for example, a pixel unit 1a including four unit pixels P arranged in two rows×two columns serves as a repeating unit, and is repeatedly arranged in an array including a row direction and a column direction.

The imaging element 10 of the present embodiment is provided with a semiconductor layer 23 including a plurality of layers between a lower electrode 21 and a photoelectric conversion layer 24 in the photoelectric conversion section 20 provided on a semiconductor substrate 30. The lower electrode 21 includes a readout electrode 21A and an accumulation electrode 21B. The semiconductor layer 23 has a configuration in which, for example, a first layer 23A and a second layer 23B are stacked in this order from a side of a lower electrode 11, and a thickness of the first layer 23A is smaller than a thickness of the second layer 23B, and is 3 nm or more 5 nm or less. This readout electrode 21A corresponds to a specific example of a “second electrode” of the present disclosure, and the accumulation electrode 21B corresponds to a specific example of a “first electrode” of the present disclosure. In addition, the first layer 23A corresponds to a specific example of a “first layer” of the present disclosure, and the second layer 23B corresponds to a specific example of a “second layer” of the present disclosure.

### (1-1. Configuration of Imaging Element)

The imaging element 10 is, for example, a so-called vertical spectroscopic imaging element in which one photoelectric conversion section 20 and two photoelectric conversion regions 32B and 32R are stacked in a vertical direction. The photoelectric conversion section 20 is provided on a side of a back surface (a first surface 30A) of the semiconductor substrate 30. The photoelectric conversion regions 32B and 32R are formed to be embedded in the semiconductor substrate 30, and are stacked in a thickness direction of the semiconductor substrate 30.

The photoelectric conversion section 20 and the photoelectric conversion regions 32B and 32R selectively detect light beams in wavelength regions different from each other to perform photoelectric conversion. For example, the photoelectric conversion section 20 acquires a green (G) color signal. The photoelectric conversion regions 32B and 32R respectively acquire blue (B) and red (R) color signals depending on a difference in absorption coefficients. This enables the imaging element 10 to acquire a plurality of types of color signals in one pixel without using color filters.

It is to be noted that, in the present embodiment, description is given of a case where electrons of electron/hole pairs (excitons) generated by photoelectric conversion are read as signal charge (in a case where an n-type semiconductor region is used as a photoelectric conversion layer). In addition, in the diagram, “+ (plus)” attached to “p” and “n” indicates a higher p-type or n-type impurity concentration.

A front surface (a second surface 30B) of the semiconductor substrate 30 is provided, for example, with floating diffusions (floating diffusion layers) FD1 (a region 36B in the semiconductor substrate 30), FD2 (a region 37C in the semiconductor substrate 30), and FD3 (a region 38C in the semiconductor substrate 30), transfer transistors Tr2 and Tr3, an amplifier transistor (modulation element) AMP, a reset transistor RST, and a selection transistor SEL. The second surface 30B of the semiconductor substrate 30 is further provided with a multilayer wiring layer 40 with a gate insulating layer 33 interposed therebetween. The multilayer wiring layer 40 has, for example, a configuration in which wiring layers 41, 42, and 43 are stacked in an insulating layer 44. A peripheral part of the semiconductor substrate 30, i.e., a peripheral region 1B around the pixel section 1A is provided with a vertical drive circuit 111, a column signal processing circuit 112, a horizontal drive circuit 113, an output circuit 114, a control circuit 115, an input/output terminal 116, and the like, which are described later.

It is to be noted that the diagram illustrates a side of the first surface 30A of the semiconductor substrate 30 as a light incident side S1, and a side of the second surface 30B thereof as a wiring layer side S2.

In the photoelectric conversion section 20, the semiconductor layer 23 and the photoelectric conversion layer 24 are stacked in this order from a side of the lower electrode 21 between the lower electrode 21 and an upper electrode 25 that are disposed to be opposed to each other. The photoelectric conversion layer 24 is formed by using an organic material. As described above, in the semiconductor layer 23, the first layer 23A and the second layer 23B are stacked in this order from the side of the lower electrode 21. The photoelectric conversion layer 24 includes a p-type semiconductor and an n-type semiconductor, and has a bulk heterojunction structure therein. The bulk heterojunction structure is a p/n junction surface formed by mixing a p-type semiconductor and an n-type semiconductor.

The photoelectric conversion section 20 further includes an insulating layer 22 between the lower electrode 21 and the semiconductor layer 23. The insulating layer 22 is provided, for example, across the entire surface of the pixel section 1A, and has an opening 22H on the readout electrode 21A that constitutes the lower electrode 21. The readout electrode 21A is electrically coupled to the semiconductor layer 23 via this opening 22H.

It is to be noted that FIG. 1 illustrates an example in which the semiconductor layer 23, the photoelectric conversion layer 24, and the upper electrodes 25 are separately formed for each imaging element 10, but the semiconductor layer 23, the photoelectric conversion layer 24, and the upper electrode 25 may be provided, for example, as a continuous layer common to a plurality of imaging elements 10.

For example, an insulating layer 26 and an interlayer insulating layer 27 are stacked between the first surface 30A of the semiconductor substrate 30 and the lower electrode 21. In the insulating layer 26, a layer (fixed charge layer) 26A having fixed electric charge and a dielectric layer 26B having an insulation property are stacked in this order from a side of the semiconductor substrate 30.

The photoelectric conversion regions 32B and 32R each allow light to be dispersed in the vertical direction by utilizing a difference in wavelengths of light beams to be absorbed in accordance with the light incidence depth in the semiconductor substrate 30 including a silicon substrate. The photoelectric conversion regions 32B and 32R each have a p-n junction in a predetermined region in the semiconductor substrate 30.

There is provided a through-electrode 34 between the first surface 30A and the second surface 30B of the semiconductor substrate 30. The through-electrode 34 is electrically coupled to the readout electrode 21A. The photoelectric conversion section 20 is coupled, via the through-electrode 34, to a gate Gamp of the amplifier transistor AMP and to one source/drain region 36B of the reset transistor RST (a reset transistor Trlrst) also serving as the floating diffusion FD1. This enables the imaging element 10 to favorably transfer carriers (electrons here) generated by the photoelectric conversion section 20 provided on the side of the first surface 30A of the semiconductor substrate 30 to the side of the second surface 30B of the semiconductor substrate 30 via the through-electrode 34 and thus to enhance the characteristics.

The lower end of the through-electrode 34 is coupled to wiring (a coupling section 41A) in the wiring layer 41, and the coupling section 41A and the gate Gamp of the amplifier transistor AMP are coupled to each other via a lower first contact 45. The coupling section 41A and the floating diffusion FD1 (region 36B) are coupled to each other, for example, via a lower second contact 46. The upper end of the through-electrode 34 is coupled to the readout electrode 21A, for example, via a pad section 39A and an upper first contact 39C.

A protective layer 51 is provided above the photoelectric conversion section 20. In the protective layer 51, for example, there are provided wiring 52 and a light-blocking film 53. The wiring 52 electrically couples the upper electrode 25 and a peripheral circuit part 130 to each other around the pixel section 1A. An optical member such as an on-chip lens 54 or a planarization layer (unillustrated) is further disposed above the protective layer 51.

In the imaging element 10 of the present embodiment, light having entered the photoelectric conversion section 20 from the light incident side S1 is absorbed by the photoelectric conversion layer 24. Excitons generated thereby move to an interface between an electron donor and an electron acceptor constituting the photoelectric conversion layer 24 to undergo exciton separation. In other words, the excitons are dissociated into electrons and holes. Carriers (electrons and holes) generated here are transported to different electrodes by diffusion due to a carrier concentration difference or by an internal electric field caused by a work function difference between an anode (e.g., the upper electrode 25) and a cathode (e.g., the lower electrode 21). The transported carriers are detected as a photocurrent. In addition, application of a potential between the lower electrode 21 and the upper electrode 25 also makes it possible to control transport directions of electrons and holes.

Hereinafter, description is given in detail of configurations, materials, and the like of each of the sections.

The photoelectric conversion section 20 is an organic photoelectric conversion element that absorbs, for example, green light corresponding to a portion or the whole of a selective wavelength region (e.g., 450 nm or more and 650 nm or less) to generate excitons.

The lower electrode 21 includes, for example, the readout electrode 21A and the accumulation electrode 21B disposed side by side with each other on an interlayer insulating layer 28. The readout electrode 21A is provided to transfer carriers generated in a photoelectric conversion layer 25 to the floating diffusion FD1, and is provided one by one for each pixel unit 1a including four pixels that are arranged in two rows×two columns, for example.

The readout electrode 21A is coupled to the floating diffusion FD1, for example, via the upper first contact 39C, the pad section 39A, the through-electrode 34, the coupling section 41A, and the lower second contact 46.

The accumulation electrode 21B is provided to accumulate, in an oxide semiconductor layer 23, electrons, for example, among the carriers generated in the photoelectric conversion layer 25, as signal charge. The accumulation electrode 21B is provided for each of the pixels. The accumulation electrode 21B is provided for each of the unit pixels P, in a region that is opposed to the light receiving surfaces of the photoelectric conversion regions 32B and 32R formed in the semiconductor substrate 30 and that covers these light receiving surfaces. It is preferable that the accumulation electrode 21B be larger than the readout electrode 21A. This makes it possible to accumulate more carriers.

The lower electrode 21 includes an electrically-conductive film having light transmissivity. The lower electrode 21 is configured by, for example, ITO (indium tin oxide). In addition to ITO, a tin oxide (SnO₂)-based material doped with a dopant or a zinc oxide-based material in which zinc oxide (ZnO) is doped with a dopant may be used as a constituent material of the lower electrode 21. Examples of the zinc oxide-based material include aluminum zinc oxide (AZO) doped with aluminum (Al) as a dopant, gallium zinc oxide (GZO) doped with gallium (Ga), and indium zinc oxide (IZO) doped with indium (In). In addition, IGZO, ITZO, CuI, InSbO₄, ZnMgO, CuInO₂, MgIN₂O₄, CdO, ZnSnO₃, or the like may also be used in addition thereto.

The insulating layer 22 is provided to electrically separate the accumulation electrode 21B and the semiconductor layer 23 from each other. The insulating layer 22 is provided, for example, above the interlayer insulating layer 27 to cover the lower electrode 21. The insulating layer 22 is provided with the opening 22H on the readout electrode 21A of the lower electrode 21, and the readout electrode 21A and the semiconductor layer 23 are electrically coupled to each other via this opening 22H. The insulating layer 22 is configured by, for example, a monolayer film including one of silicon oxide (SiOₓ), silicon nitride (SiNₓ), silicon oxynitride (SiON), or the like, or a stacked film including two or more thereof. The insulating layer 22 has a thickness of 20 nm to 500 nm, for example.

The semiconductor layer 23 is provided to accumulate carriers (electrons) generated by the photoelectric conversion layer 24. As described above, the semiconductor layer 23 is provided between the lower electrode 21 and the photoelectric conversion layer 24, and has a stacked structure in which the first layer 23A and the second layer 23B are stacked in this order from the side of the lower electrode 21. The electrons generated by the photoelectric conversion layer 24 are accumulated above the accumulation electrode 21B from the vicinity of an interface between the insulating layer 22 and the first layer 23A to the entire semiconductor layer 23, and are transferred to the readout electrode 21A via the first layer 23A. Although described in detail later, the electrons accumulated above the accumulation electrode 21B are transferred to the readout electrode 21A by controlling a potential of the accumulation electrode 21B to generate a potential gradient. The electrons are transferred from the readout electrode 21A to the floating diffusion FD1.

The first layer 23A and the second layer 23B each have a predetermined thickness. Specifically, a thickness (t1) of the first layer 23A is smaller than a thickness (t2) of the second layer 23B; for example, a ratio (t1/t2) between the thickness (t1) of the first layer 23A and the thickness (t2) of the second layer 23B is 0.16 or less.

It is possible to form the semiconductor layer 23 (the first layer 23A and the second layer 23B) by using, for example, the following materials. The imaging element 10 of the present embodiment reads, as signal charge, electrons of the carriers generated by the photoelectric conversion layer 24. This makes it possible to form the semiconductor layer 23 by using an n-type oxide semiconductor material. Specific examples thereof include IGZO (In—Ga—Zn—O-based oxide semiconductor), ITZO (In—Sn—Zn—O-based oxide semiconductor), ZTO (Zn—Sn—O-based oxide semiconductor), IGZTO (In—Ga—Zn—Sn—O-based oxide semiconductor), GTO (Ga—Sn—O-based oxide semiconductor), IGO (In—Ga—O-based oxide semiconductor), or the like. In addition, it is possible to use AlZnO, GaZnO, InZnO, or the like in which the above-described oxide semiconductor is doped with aluminum (Al), gallium (Ga), indium (In), or the like as a dopant, or to use a material including CuI, InSbO₄, ZnMgO, CuInO₂, MgIN₂O₄, CdO, or the like.

At least one of the above-described oxide semiconductor materials is preferably used for the first layer 23A and the second layer 23B; above all, indium oxide such as IGZO is preferably used. For example, the first layer 23A is formed using indium oxide having a higher indium content ratio than that of indium oxide constituting the second layer 23B. As an example, the first layer 23A may be formed using IGZO with a ratio of In:Ga:Zn=4:2:3, and the second layer 23B may be formed using IGZO with a ratio of In:Ga:Zn=1:1:1.

The first layer 23A and the second layer 23B each have, for example, a crystalline property or an amorphous property. Alternatively, one of the first layer 23A or the second layer 23B may have a crystalline property and the other may have an amorphous property. In addition, in a case where the first layer 23A and the second layer 23B each have a crystalline property, the first layer 23A may have a stacked structure of an amorphous layer and a crystalline layer. Specifically, a portion (an initial layer having a film thickness of several nm at the time when the first layer 23A is formed) of the first layer 23A may be an amorphous layer. In a case where the first layer 23A and the second layer 23B are each formed as a crystalline layer, the first layer 23A serves the role of a seed crystal of the second layer 23B. This makes it possible to form the second layer 23B having favorable film quality. It is thus possible to reduce a defect level at an interface between the first layer 23A and the second layer 23B. In a case where the first layer 23A is set as a crystalline layer and the second layer 23B is set as an amorphous layer, impurities in the layers are reduced as compared with a case of direct formation on the insulating layer 22. This makes it possible to reduce the defect level caused by the impurities. In addition, the inhibition of crystalline growth caused by the impurities is also reduced, thus making it possible to increase a crystalline property. In a case where the first layer 23A is set as an amorphous layer and the second layer 23B is set as a crystalline layer and in a case where the first layer 23A and the second layer 23B are each set as an amorphous layer, the impurities in silicon are also reduced. This makes it possible to reduce the defect level.

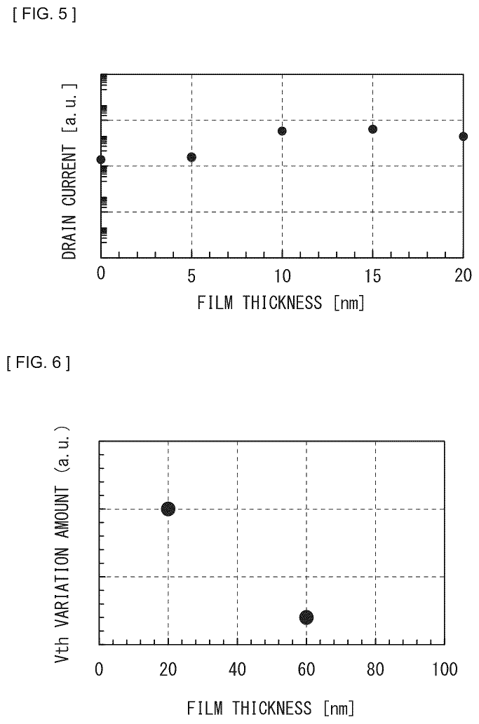

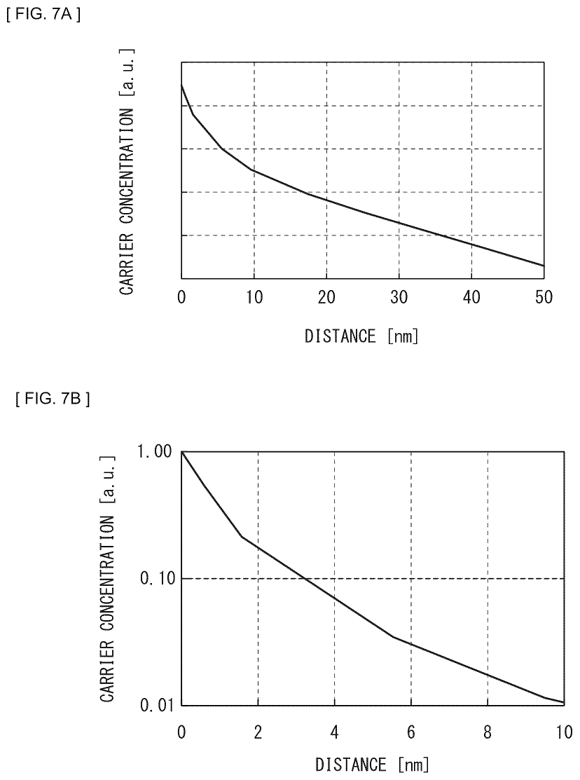

FIG. 4 illustrates a relationship between a delayed electric charge amount and a film thickness of the first layer 23A. The delayed electric charge amount refers to an amount of electric charge having been transferred after elapse of a certain period of time from the start of the transfer at the time when transferring electric charge accumulated in the semiconductor layer 23 to the floating diffusion FD1; a smaller value of the delayed electric charge amount indicates more favorable carrier conductivity. FIG. 5 illustrates a relationship between a drain current and a film thickness of the first layer 23A. The drain current is a current flowing to a drain when the semiconductor layer 23 is set as a channel layer in the transistor; a smaller value of the drain current indicates higher reliability. FIG. 6 illustrates a relationship between a variation amount of a threshold voltage and a film thickness of the second layer 23B. FIG. 7A illustrates a simulation result of a relationship between a carrier concentration and a distance from an interface between the insulating layer 22 and the semiconductor layer 23. FIG. 7B is an enlarged view of the range of the film thickness from 0 nm to 10 nm illustrated in FIG. 7A, with the vertical axis being standardized.

It is appreciated from FIG. 4 that the first layer 23A having a predetermined film thickness makes it possible to maintain favorable carrier conductivity. It is appreciated from FIG. 5 that the first layer 23A having a thickness of several nm or less exerts no influence on the reliability. It can be said, from the results of FIGS. 4 and 5, setting the thickness of the first layer 23A to, for example, 5 nm or less makes it possible to improve the reliability while maintaining the carrier conductivity. Meanwhile, electrons to be accumulated in the semiconductor layer 23 are accumulated in the vicinity of the interface between the insulating layer 22 and the first layer 23A. The electrons accumulated in the semiconductor layer 23 is decreased as being away from the interface between the insulating layer 22 and the first layer 23A. For example, when the distance from the interface between the insulating layer 22 and the first layer 23A is about 3 nm, the carrier concentration is decreased by about an order of magnitude. From those described above, the thickness of the first layer 23A is set to 3 nm or more and 5 nm or less.

It is appreciated from FIG. 6 that increasing the thickness of the second layer 23B beyond a predetermined thickness reduces the variation of the threshold voltage (Vth). For example, in a case where the second layer 23B has a decreased film thickness of 20 nm, a back channel occurs due to fixed electric charge on a surface of the second layer 23B, thus increasing the variation of the threshold voltage (Vth). In a case where the second layer 23B has an increased film thickness of 60 nm, the variation of the threshold voltage (Vth) is reduced. Meanwhile, when simulating a film thickness distribution of the carrier concentration upon accumulation of electrons in the second layer 23B at an actual driving voltage, it is appreciated that the carrier (electron) concentration is decreased as the distance is increased from the interface between the insulating layer 22 and the semiconductor layer 23, as illustrated in FIG. 7A. However, when there are many electrons on a surface of the semiconductor layer 23, the number of electrons trapped by the fixed electric charge is increased, thus increasing the variation of the threshold voltage (Vth). Therefore, when the carrier concentration in a state where no voltage is applied is set to 1.0E+16 cm⁻³, for example, and electrons on the surface is less than the value in a state where electrons are accumulated in the semiconductor layer 23, the variation amount of the threshold voltage (Vth) is regarded as being within a standard. That is, the thickness of the semiconductor layer 23 is 35 nm or more from FIG. 7A. Here, the thickness of the first layer 23A is set to 3 nm or more and 5 nm or less, as described above. Therefore, the thickness of the second layer 23B is 32 nm or more.

The photoelectric conversion layer 24 converts optical energy to electric energy. The photoelectric conversion layer 24 includes, for example, two or more types of organic materials (a p-type semiconductor material or an n-type semiconductor material) that each function as a p-type semiconductor or an n-type semiconductor. The photoelectric conversion layer 24 has, therein, a junction surface (p/n junction surface) between the p-type semiconductor material and the n-type semiconductor material. The p-type semiconductor relatively functions as an electron donor (donor), and the n-type semiconductor relatively functions as an electron acceptor (acceptor). The photoelectric conversion layer 24 provides a field where excitons generated in absorbing light are separated into electrons and holes. Specifically, excitons are separated into electrons and holes at the interface (p/n junction surface) between the electron donor and the electron acceptor.

The photoelectric conversion layer 24 may include an organic material, i.e., a so-called coloring material in addition to the p-type semiconductor material and the n-type semiconductor material. The organic material, i.e., the coloring material photoelectrically converts light in a predetermined wavelength region while transmitting light in another wavelength region. In a case where the photoelectric conversion layer 24 is formed by using the three types of organic materials of a p-type semiconductor material, an n-type semiconductor material, and a coloring material, it is preferable that the p-type semiconductor material and the n-type semiconductor material be materials each having light transmissivity in a visible region (e.g., 450 nm to 800 nm). The photoelectric conversion layer 24 has a thickness of 50 nm to 500 nm, for example.

Examples of organic materials constituting the photoelectric conversion layer 24 include a quinacridone derivative, a naphthalene derivative, an anthracene derivative, a phenanthrene derivative, a tetracene derivative, a pyrene derivative, a perylene derivative, and a fluoranthene derivative. The photoelectric conversion layer 24 includes two or more of the above-described organic materials in combination. The above-described organic materials function as a p-type semiconductor or an n-type semiconductor depending on the combination.

It is to be noted that the organic materials constituting the photoelectric conversion layer 24 are not limited in particular. It is possible to use, for example, a polymer such as phenylenevinylene, fluorene, carbazole, indole, pyrene, pyrrole, picoline, thiophene, acetylene, diacetylene, or the like, or a derivative thereof, in addition to the above-described organic materials. Alternatively, it is possible to use a metal complex dye, a cyanine-based dye, a merocyanine-based dye, a phenylxanthene-based dye, a triphenylmethane-based dye, a rhodacyanine-based dye, a xanthene-based dye, a macrocyclic azaannulene-based dye, an azulene-based dye, a naphthoquinone-based dye, an anthraquinone-based dye, a chain compound in which a fused polycyclic aromatic group such as pyrene, an aromatic ring, or a heterocyclic compound is fused, a cyanine-like dye bonded by two nitrogen-containing hetero rings including quinoline, benzothiazole, benzoxazole, and the like that have a squarylium group and a croconic methine group as a bonded chain or by a squarylium group and a croconic methine group, or the like. It is to be noted that examples of the metal complex dye include a dithiol metal complex-based dye, a metallophthalocyanine dye, a metalloporphyrine dye, or a ruthenium complex dye. A ruthenium complex dye is preferable in particular among them, but the metal complex dye is not limited thereto.

The upper electrode 25 includes an electrically-conductive film having light transmissivity in the same manner as the upper electrode 25. The upper electrode 25 is configured by, for example, ITO (indium tin oxide). In addition to this ITO, a tin oxide (SnO₂)-based material doped with a dopant or a zinc oxide-based material in which zinc oxide (ZnO) is doped with a dopant may be used as a constituent material of the upper electrode 25. Examples of the zinc oxide-based material include aluminum zinc oxide (AZO) doped with aluminum (Al) as a dopant, gallium zinc oxide (GZO) doped with gallium (Ga), and indium zinc oxide (IZO) doped with indium (In). In addition, IGZO, ITZO, CuI, InSbO₄, ZnMgO, CuInO₂, MgIN₂O₄, CdO, ZnSnO₃, or the like may also be used in addition thereto. The upper electrodes 25 may be separated for each of the pixels, or the upper electrode 25 may be formed as an electrode common to the pixels. The upper electrode 25 has a thickness of 10 nm to 200 nm, for example.

It is to be noted that the photoelectric conversion section 20 may be provided with other layers between the lower electrode 21 and the photoelectric conversion layer 24 (e.g., between the semiconductor layer 23 and the photoelectric conversion layer 24) and between the photoelectric conversion layer 24 and the upper electrode 25. For example, in the photoelectric conversion section 20, the semiconductor layer 23, a buffer layer also serving as an electron blocking film, the photoelectric conversion layer 24, a buffer layer also serving as a hole blocking film, a work function adjustment layer, and the like may be stacked in order from the side of the lower electrode 21. In addition, the photoelectric conversion layer 24 may have a pin bulk heterostructure in which, for example, a p-type blocking layer, a layer (i-layer) including a p-type semiconductor and an n-type semiconductor, and an n-type blocking layer are stacked.

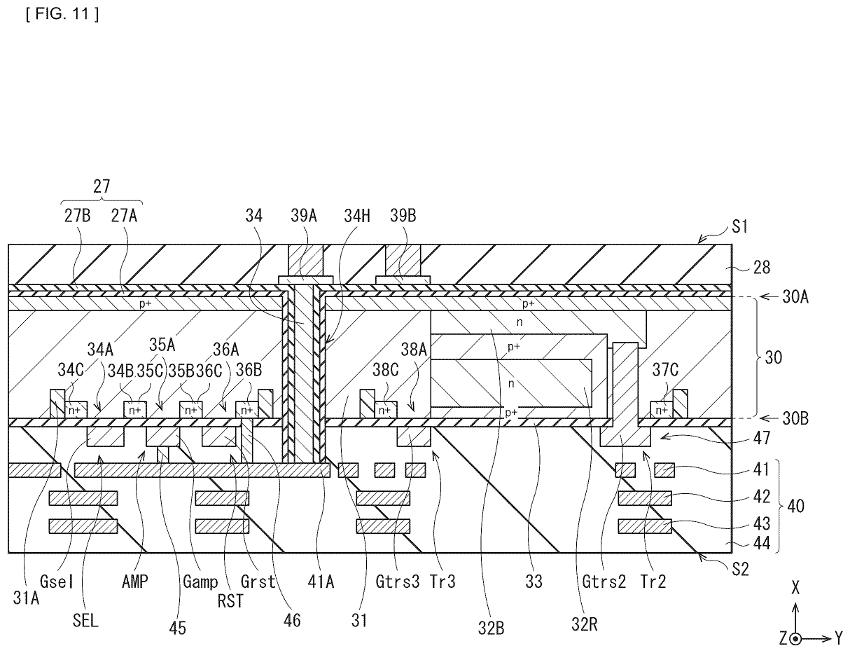

The insulating layer 26 covers the first surface 30A of the semiconductor substrate 30 and reduces the interface state with the semiconductor substrate 30. In addition, the insulating layer 26 is provided to suppress generation of a dark current from the interface with the semiconductor substrate 30. In addition, the insulating layer 26 extends from the first surface 30A of the semiconductor substrate 30 to a side surface of the opening 34H (see FIG. 11) in which the through-electrode 34 is formed. The through-electrode 34 penetrates the semiconductor substrate 30. The insulating layer 26 has, for example, a stacked structure of the fixed charge layer 26A and the dielectric layer 26B.

The fixed charge layer 26A may be a film having positive fixed electric charge, or may be a film having negative fixed electric charge. As for the constituent material, the fixed charge layer 26A is preferably formed using an electrically-conductive material or a semiconductor material having a wider band gap than that of the semiconductor substrate 30. This makes it possible to suppress generation of a dark current at the interface of the semiconductor substrate 30. Examples of the constituent material of the fixed charge layer 26A include hafnium oxide (HfOₓ), aluminum oxide (AlOₓ), zirconium oxide (ZrOₓ), tantalum oxide (TaOₓ), titanium oxide (TiOₓ), lanthanum oxide (LaOₓ), praseodymium oxide (PrOₓ), cerium oxide (CeOₓ), neodymium oxide (NdOₓ), promethium oxide (PmOₓ), samarium oxide (SmOₓ), europium oxide (EuOₓ), gadolinium oxide (GdOₓ), terbium oxide (TbOₓ), dysprosium oxide (DyOₓ), holmium oxide (HoOₓ), thulium oxide (TmOₓ), ytterbium oxide (YbOₓ), lutetium oxide (LuOₓ), yttrium oxide (YOₓ), hafnium nitride (HfNₓ), aluminum nitride (AlNₓ), hafnium oxynitride (HfOₓN_{y}), and aluminum oxynitride (AlOₓN_{y}).

The dielectric layer 26B is provided to prevent light reflection caused by a refractive index difference between the semiconductor substrate 30 and the interlayer insulating layer 27. As a constituent material of the dielectric layer 26B, it is preferable to adopt a material having a refractive index between a refractive index of the semiconductor substrate 30 and a refractive index of the interlayer insulating layer 27. Examples of the constituent material of the dielectric layer 26B include silicon oxide, TEOS, silicon nitride, silicon oxynitride (SiON), and the like.

The interlayer insulating layer 27 is configured by, for example, a monolayer film including one of silicon oxide, silicon nitride, silicon oxynitride, or the like, or a stacked film including two or more thereof.

There is provided a shield electrode 28 on the interlayer insulating layer 27 together with the lower electrode 21. The shield electrode 28 is provided to prevent capacitive coupling between the adjacent pixel units 1a. For example, the shield electrode 28 is provided around the pixel unit 1a including four pixels arranged in two rows×two columns, and a fixed potential is applied to the shield electrode 28. The shield electrode 28 further extends between pixels adjacent in the row direction (Z-axis direction) and the column direction (X-axis direction) in the pixel unit 1a.

The semiconductor substrate 30 is configured by, for example, an n-type silicon (Si) substrate, and includes a p-well 31 in a predetermined region.

The photoelectric conversion regions 32B and 32R are each configured by a photodiode (PD) having a p-n junction in a predetermined region in the semiconductor substrate 30, and enable light to be dispersed in the vertical direction by utilizing a difference in wavelengths of light beams to be absorbed depending on incidence depth of light in the Si substrate. The photoelectric conversion region 32B, for example, selectively detects blue light and accumulates signal charge corresponding to blue; the photoelectric conversion region 32B is provided at a depth at which the blue light is able to be efficiently subjected to photoelectric conversion. The photoelectric conversion region 32R, for example, selectively detects red light and accumulates signal charge corresponding to red; the photoelectric conversion region 32R is provided at a depth at which the red light is able to be efficiently subjected to photoelectric conversion. It is to be noted that blue (B) is a color corresponding to a wavelength region of 450 nm to 495 nm, for example, and red (R) is a color corresponding to a wavelength region of 620 nm to 750 nm, for example. It is sufficient for each of the photoelectric conversion regions 32B and 32R to be able to detect light in a portion or the whole of each wavelength region.

The photoelectric conversion region 32B includes, for example, a p+ region serving as a hole accumulation layer and an n region serving as an electron accumulation layer. The photoelectric conversion region 32R includes, for example, a p+ region serving as a hole accumulation layer and an n region serving as an electron accumulation layer (having a p-n-p stacked structure). The n region of the photoelectric conversion region 32B is coupled to the vertical transfer transistor Tr2. The p+ region of the photoelectric conversion region 32B bends along the transfer transistor Tr2, and is linked to the p+ region of the photoelectric conversion region 32R.

The gate insulating layer 33 is configured by, for example, a monolayer film including one of silicon oxide, silicon nitride, silicon oxynitride, or the like, or a stacked film including two or more thereof.

The through-electrode 34 is provided between the first surface 30A and the second surface 30B of the semiconductor substrate 30. The through-electrode 34 has a function as a connector for the photoelectric conversion section 20 and the gate Gamp of the amplifier transistor AMP as well as the floating diffusion FD1, and serves as a transmission path for the carriers generated by the photoelectric conversion section 20. A reset gate Grst of the reset transistor RST is disposed next to the floating diffusion FD1 (one source/drain region 36B of the reset transistor RST). This enables the reset transistor RST to reset the carriers accumulated in the floating diffusion FD1.

The upper first contact 24A, the upper second contact 24B, the upper third contact 24C, the pad sections 39A, 39B, and 39C, the wiring layers 41, 42, and 43, the lower first contact 45, the lower second contact 46, and a gate wiring layer 47 may be formed using a doped silicon material such as PDAS (Phosphorus Doped Amorphous Silicon) or a metal material such as Al, W, Ti, Co, Hf, or Ta.

The pad sections 39A and 39B, the upper first contact 39C, an upper second contact 39D, the lower first contact 45, the lower second contact 46, and the wiring 52 may be formed using a doped silicon material such as PDAS (Phosphorus Doped Amorphous Silicon), or a metal material such as aluminum (Al), tungsten (W), titanium (Ti), cobalt (Co), hafnium (Hf), or tantalum (Ta).

The protective layer 51 and the on-chip lens 54 are configured by a material having light transmissivity, and are configured by, for example, a monolayer film including one of silicon oxide, silicon nitride, silicon oxynitride, or the like, or a stacked film including two or more thereof. The protective layer 51 has a thickness of, for example, 100 nm to 30000 nm.

For example, the light-blocking film 53 is provided, in the protective layer 51 together with the wiring 52, to cover a region of the readout electrode 21A in direct contact with the semiconductor layer 23 without covering at least the accumulation electrode 21B. The light-blocking film 53 may be formed using, for example, tungsten (W), aluminum (Al), an alloy of Al and copper (Cu), or the like.

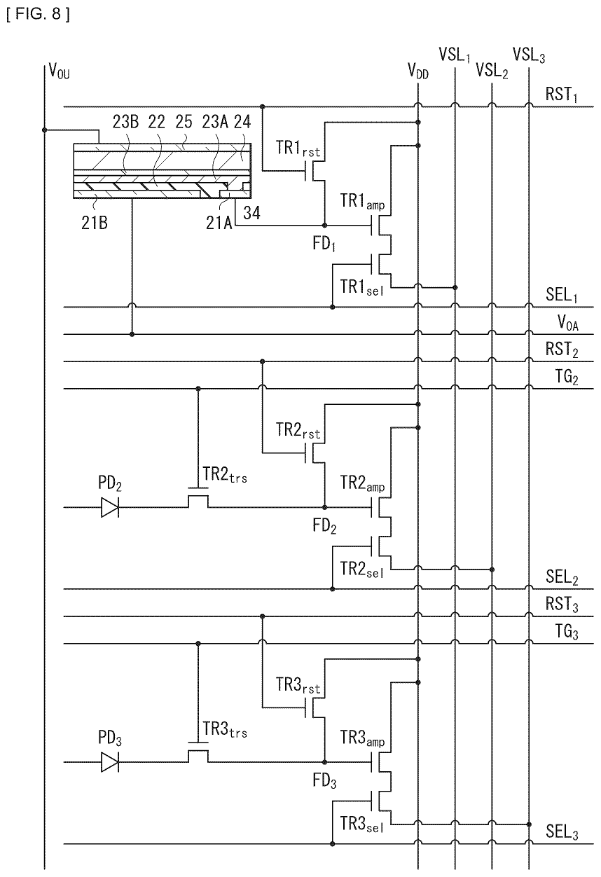

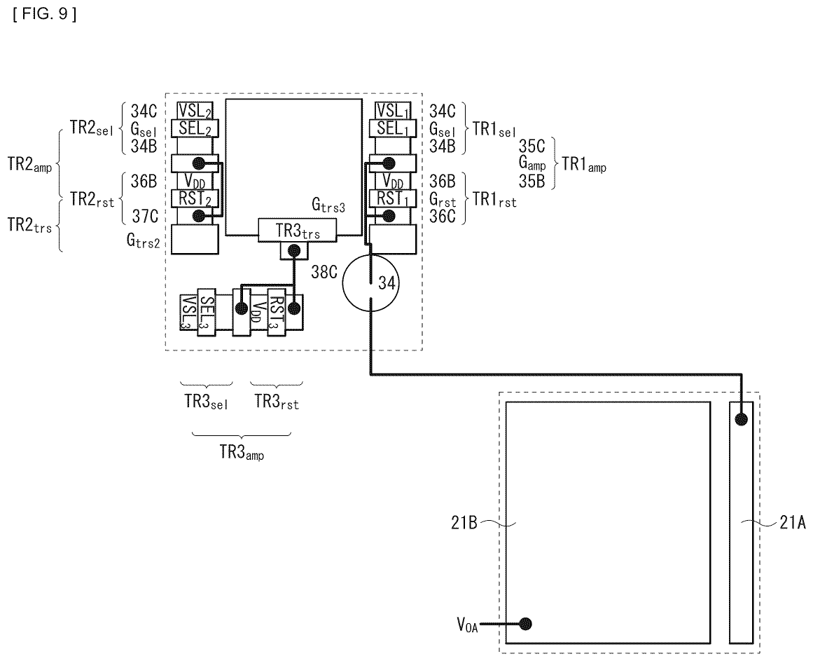

FIG. 8 is an equivalent circuit diagram of the imaging element 10 illustrated in FIG. 1. FIG. 9 schematically illustrates an arrangement of transistors constituting a controller and the lower electrode 21 of the imaging element 10 illustrated in FIG. 1.

The reset transistor RST (a reset transistor TR1rst) resets carriers transferred from the photoelectric conversion section 20 to the floating diffusion FD1, and is configured by a MOS transistor, for example. Specifically, the reset transistor TR1rst is configured by the reset gate Grst, a channel formation region 36A, and source/drain regions 36B and 36C. The reset gate Grst is coupled to a reset line RST1. The one source/drain region 36B of the reset transistor TR1rst also serves as the floating diffusion FD1. The other source/drain region 36C constituting the reset transistor TR1rst is coupled to a power supply line VDD.

The amplifier transistor AMP (an amplifier transistor TR1amp) is a modulation element that modulates, to a voltage, the amount of electric charge generated by the photoelectric conversion section 20, and is configured by a MOS transistor, for example. Specifically, the amplifier transistor AMP is configured by the gate Gamp, a channel formation region 35A, and the source/drain regions 35B and 35C. The gate Gamp is coupled to the readout electrode 21A and the one source/drain region 36B (floating diffusion FD1) of the reset transistor TR1rst via the lower first contact 45, the coupling section 41A, the lower second contact 46, the through-electrode 34, and the like. In addition, the one source/drain region 35B shares a region with the other source/drain region 36C constituting the reset transistor TR1rst, and is coupled to the power supply line VDD.

A selection transistor SEL (a selection transistor TR1sel) is configured by a gate Gsel, a channel formation region 34A, and source/drain regions 34B and 34C. The gate Gsel is coupled to a selection line SEL1. The one source/drain region 34B shares a region with the other source/drain region 35C constituting the amplifier transistor AMP, and the other source/drain region 34C is coupled to a signal line (data output line) VSL1.

The transfer transistor TR2 (a transfer transistor TR2trs) is provided to transfer, to the floating diffusion FD2, signal charge corresponding to blue that has been generated and accumulated in the photoelectric conversion region 32B. The photoelectric conversion region 32B is formed at a deep position from the second surface 30B of the semiconductor substrate 30, and it is thus preferable that the transfer transistor TR2trs of the photoelectric conversion region 32B be configured by a vertical transistor. The transfer transistor TR2trs is coupled to a transfer gate line TG2. The floating diffusion FD2 is provided in the region 37C near a gate Gtrs2 of the transfer transistor TR2trs. The carriers accumulated in the photoelectric conversion region 32B are read to the floating diffusion FD2 via a transfer channel formed along the gate Gtrs2.

The transfer transistor TR3 (a transfer transistor TR3trs) is provided to transfer, to the floating diffusion FD3, signal charge corresponding to red that has been generated and accumulated in the photoelectric conversion region 32R. The transfer transistor TR3 (transfer transistor TR3trs) is configured by, for example, a MOS transistor. The transfer transistor TR3trs is coupled to a transfer gate line TG3. The floating diffusion FD3 is provided in a region 38C near a gate Gtrs3 of the transfer transistor TR3trs. The carriers accumulated in the photoelectric conversion region 32R are read to the floating diffusion FD3 via a transfer channel formed along the gate Gtrs3.

The side of the second surface 30B of the semiconductor substrate 30 is further provided with a reset transistor TR2rst, an amplifier transistor TR2amp, and a selection transistor TR2sel constituting the controller of the photoelectric conversion region 32B. Further, there are provided a reset transistor TR3rst, an amplifier transistor TR3amp, and a selection transistor TR3sel constituting the controller of the photoelectric conversion region 32R.

The reset transistor TR2rst is configured by a gate, a channel formation region, and source/drain regions. The gate of the reset transistor TR2rst is coupled to a reset line RST2, and the one source/drain region of the reset transistor TR2rst is coupled to the power supply line VDD. The other source/drain region of the reset transistor TR2rst also serves as the floating diffusion FD2.

The amplifier transistor TR2amp is configured by a gate, a channel formation region, and source/drain regions. The gate is coupled to the other source/drain region (floating diffusion FD2) of the reset transistor TR2rst. The one source/drain region constituting the amplifier transistor TR2amp shares a region with the one source/drain region constituting the reset transistor TR2rst, and is coupled to the power supply line VDD.

The selection transistor TR2sel is configured by a gate, a channel formation region, and source/drain regions. The gate is coupled to a selection line SEL2. The one source/drain region constituting the selection transistor TR2sel shares a region with the other source/drain region constituting the amplifier transistor TR2amp. The other source/drain region constituting the selection transistor TR2sel is coupled to a signal line (data output line) VSL2.

The reset transistor TR3rst is configured by a gate, a channel formation region, and source/drain regions. The gate of the reset transistor TR3rst is coupled to a reset line RST3, and the one source/drain region constituting the reset transistor TR3rst is coupled to the power supply line VDD. The other source/drain region constituting the reset transistor TR3rst also serves as the floating diffusion FD3.

The amplifier transistor TR3amp is configured by a gate, a channel formation region, and source/drain regions. The gate is coupled to the other source/drain region (floating diffusion FD3) constituting the reset transistor TR3rst. The one source/drain region constituting the amplifier transistor TR3amp shares a region with the one source/drain region constituting the reset transistor TR3rst, and is coupled to the power supply line VDD.

The selection transistor TR3sel is configured by a gate, a channel formation region, and source/drain regions. The gate is coupled to a selection line SEL3. The one source/drain region constituting the selection transistor TR3sel shares a region with the other source/drain region constituting the amplifier transistor TR3amp. The other source/drain region constituting the selection transistor TR3sel is coupled to a signal line (data output line) VSL3.

The reset lines RST1, RST2, and RST3, the selection lines SEL1, SEL2, and SEL3, and the transfer gate lines TG2 and TG3 are each coupled to a vertical drive circuit constituting a drive circuit. The signal lines (data output lines) VSL1, VSL2, and VSL3 are coupled to a column signal processing circuit 112 constituting the drive circuit.

### (1-2. Method of Manufacturing Imaging Element)

The imaging element 10 according to the present embodiment may be manufactured, for example, as follows.

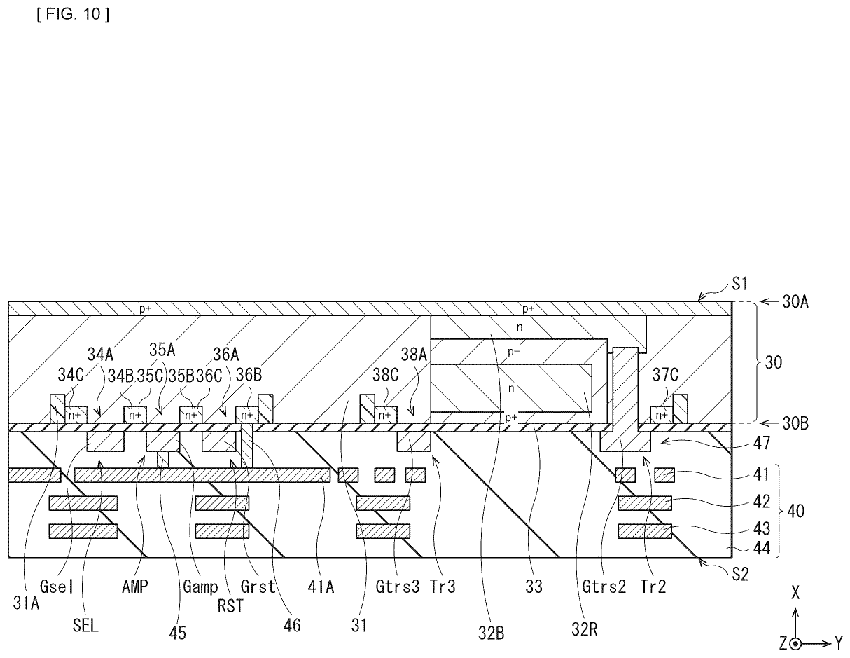

FIGS. 10 to 15 illustrate a method of manufacturing the imaging element 10 in the order of steps. First, as illustrated in FIG. 10, for example, the p-well 31 is formed in the semiconductor substrate 30, and the photoelectric conversion regions 32B and 32R of an n type, for example, are formed in this p-well 31. A p+ region is formed near the first surface 30A of the semiconductor substrate 30.

As also illustrated in FIG. 10, for example, n+ regions that serve as the floating diffusions FD1 to FD3 are formed on the second surface 30B of the semiconductor substrate 30, and the gate insulating layer 33 and the gate wiring layer 47 are then formed. The gate wiring layer 47 includes the respective gates of the transfer transistor Tr2, the transfer transistor Tr3, the selection transistor SEL, the amplifier transistor AMP, and the reset transistor RST. This forms the transfer transistor Tr2, the transfer transistor Tr3, the selection transistor SEL, the amplifier transistor AMP, and the reset transistor RST. Further, the multilayer wiring layer 40 is formed on the second surface 30B of the semiconductor substrate 30. The multilayer wiring layer 40 includes the wiring layers 41 to 43 and the insulating layer 44. The wiring layers 41 to 43 include the lower first contact 45, the lower second contact 46, and the coupling section 41A.

As the base of the semiconductor substrate 30, for example, an SOI (Silicon on Insulator) substrate is used in which the semiconductor substrate 30, an embedded oxide film (unillustrated), and a holding substrate (unillustrated) are stacked. Although not illustrated in FIG. 10, the embedded oxide film and the holding substrate are joined to the first surface 30A of the semiconductor substrate 30. After ion implantation, annealing treatment is performed.

Next, a support substrate (unillustrated), another semiconductor base, or the like is joined onto the multilayer wiring layer 40 provided on the side of the second surface 30B of the semiconductor substrate 30, and the substrate is turned upside down. Subsequently, the semiconductor substrate 30 is separated from the embedded oxide film and the holding substrate of the SOI substrate to expose the first surface 30A of the semiconductor substrate 30. The above-described steps may be performed with a technique used in a normal CMOS process such as ion implantation and CVD (Chemical Vapor Deposition) methods.

Next, as illustrated in FIG. 11, the semiconductor substrate 30 is worked from the side of the first surface 30A, for example, by dry etching to form, for example, an annular opening 34H. As for a depth, the opening 34H penetrates from the first surface 30A to the second surface 30B of the semiconductor substrate 30, and reaches, for example, the coupling section 41A, as illustrated in FIG. 11.

Subsequently, for example, the fixed charge layer 26A and the dielectric layer 26B are formed in order on the first surface 30A of the semiconductor substrate 30 and on a side surface of the opening 34H. The fixed charge layer 26A may be formed by forming a hafnium oxide film or an aluminum oxide film using an atomic layer deposition method (ALD method), for example. The dielectric layer 26B may be formed by forming a silicon oxide film using a plasma CVD method, for example. Next, for example, the pad sections 39A and 39B are formed at predetermined positions on the dielectric layer 26B. In the pad sections 39A and 39B, a barrier metal including a stacked film (Ti/TiN film) of titanium and titanium nitride and a tungsten film are stacked. This enables the pad sections 39A and 39B to be used as light-blocking films. Thereafter, the interlayer insulating layer 27 is formed on the dielectric layer 26B and the pad sections 39A and 39B, and a surface of the interlayer insulating layer 27 is planarized using a CMP (Chemical Mechanical Polishing) method.

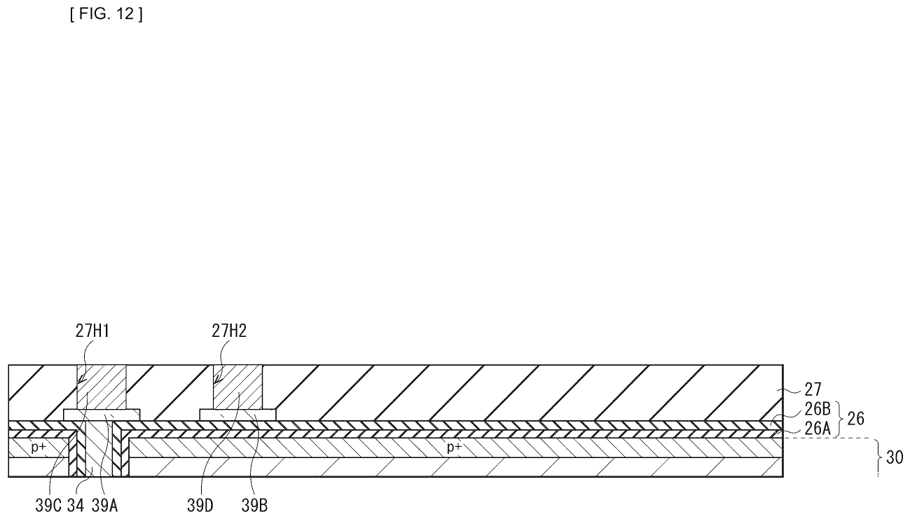

Subsequently, as illustrated in FIG. 12, openings 27H1 and 27H2 are formed, respectively, on the pad sections 39A and 39B, and then an electrically-conductive material such as Al, for example, is embedded in the openings 27H1 and 27H2 to form the upper first contact 39C and the upper second contact 39D.

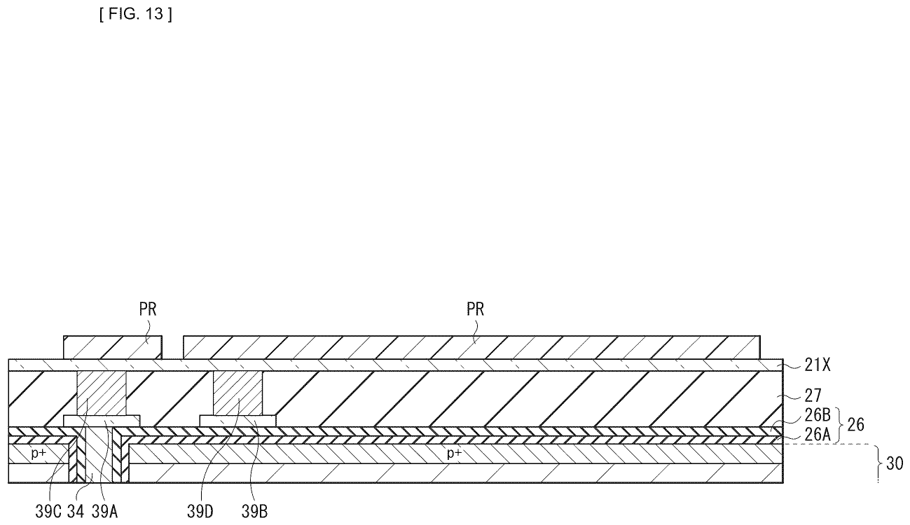

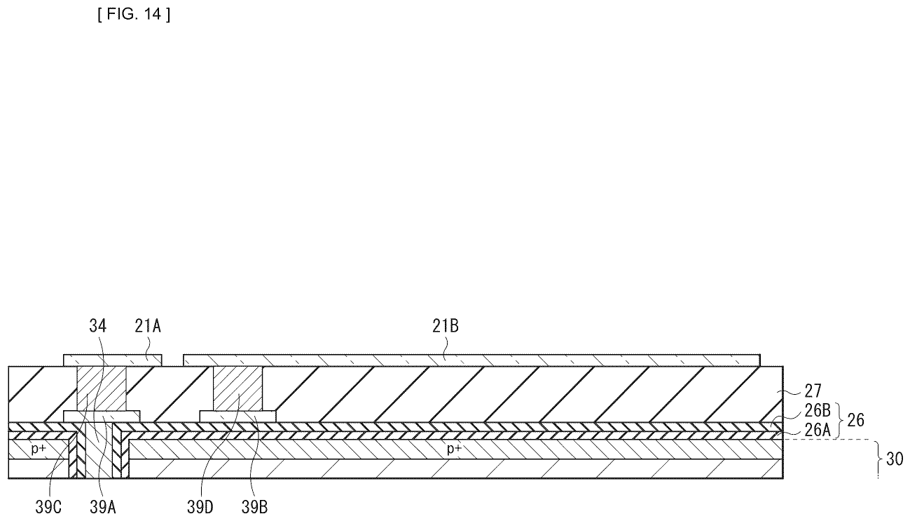

Next, as illustrated in FIG. 13, for example, an electrically-conductive film 21x is formed on the interlayer insulating layer 27 by a sputtering method, and is then patterned using a photolithography technique. Specifically, a photoresist PR is formed at a predetermined position of the electrically-conductive film 21x, and then dry etching or wet etching is used to work the electrically-conductive film 21x. Thereafter, the photoresist PR is removed to thereby form the readout electrode 21A and the accumulation electrode 21B, as illustrated in FIG. 14.

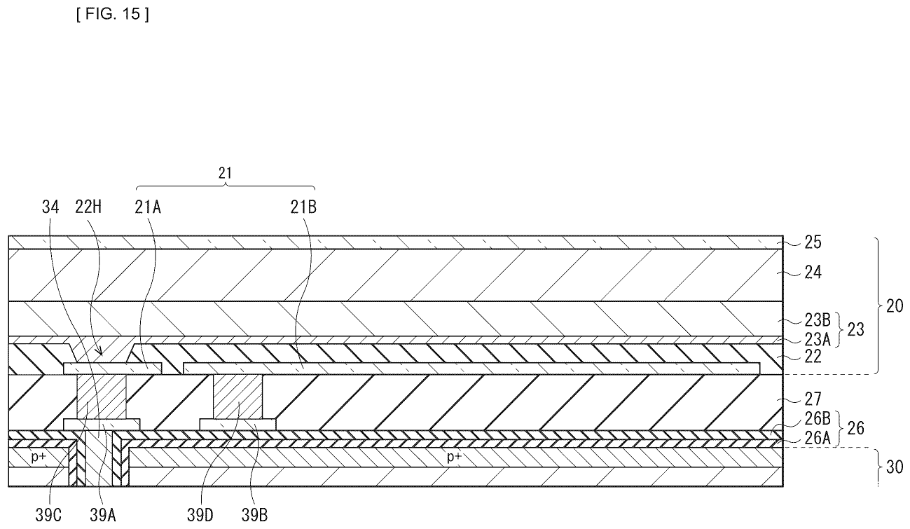

Subsequently, as illustrated in FIG. 15, the insulating layer 22, the semiconductor layer 23 including the first layer 23A and the second layer 23B, the photoelectric conversion layer 24, and the upper electrode 25 are formed. As for the insulating layer 22, for example, a silicon oxide film is formed using the ALD method, and then a surface of the insulating layer 22 is planarized using the CMP method. Thereafter, the opening 22H is formed on the readout electrode 21A using the wet etching, for example. The semiconductor layer 23 (the first layer 23A and the second layer 23B) may be formed using a sputtering method, for example. The photoelectric conversion layer 24 is formed using vacuum deposition method, for example. The upper electrode 25 is formed using a sputtering method, for example, in the same manner as the lower electrode 21. Finally, the on-chip lens 54 and the protective layer 51 including the wiring 52 and the light-blocking film 53 are disposed on the upper electrode 25. As described above, the imaging element 10 illustrated in FIG. 1 is completed.

It is to be noted that, in a case where another layer including an organic material such as a buffer layer also serving as an electron blocking film, a buffer layer also serving as a hole blocking film, or a work function adjustment layer is formed between the semiconductor layer 23 and the photoelectric conversion layer 24 and between the photoelectric conversion layer 24 and the upper electrode 25 as described above, it is preferable to form the layers continuously (in an in-situ vacuum process) in a vacuum step. In addition, the method of forming the photoelectric conversion layer 24 is not necessarily limited to an approach that uses a vacuum deposition method. For example, a spin coating technique, a printing technique, or the like may be used. Further, examples of a method of forming transparent electrodes (the lower electrode 21 and the upper electrode 25) include, depending on a material constituting the transparent electrode, a physical vapor deposition method (PVD method) such as a vacuum deposition method, a reactive deposition method, an electron beam deposition method, or an ion plating method, a pyrosol method, a method of pyrolyzing an organic metal compound, a spray method, a dip method, various CVD methods including an MOCVD method, an electroless plating method, and an electroplating method, in addition to the sputtering method.

### (1-3. Signal Acquisition Operation in Imaging Element)

When light enters the photoelectric conversion section 20 via the on-chip lens 54 in the imaging element 10, the light passes through the photoelectric conversion section 20 and the photoelectric conversion regions 32B and 32R in this order. While the light passes through the photoelectric conversion section 20 and the photoelectric conversion regions 32B and 32R, the light is photoelectrically converted for each of color light beams of green (G), blue (B), and red (R). The following describes operations of acquiring signals of the respective colors.

### (Acquisition of Green Color Signal by Photoelectric Conversion Section 20)

First, green light of the light beams having entered the imaging element 10 is selectively detected (absorbed) and photoelectrically converted by the photoelectric conversion section 20.

The photoelectric conversion section 20 is coupled to the gate Gamp of the amplifier transistor TR1amp and the floating diffusion FD1 via the through-electrode 34. Thus, electrons of excitons generated by the photoelectric conversion section 20 are taken out from the side of the lower electrode 21, transferred to the side of the second surface 30S2 of the semiconductor substrate 30 via the through-electrode 34, and accumulated in the floating diffusion FD1. At the same time, the amplifier transistor TR1amp modulates the amount of electric charge generated by the photoelectric conversion section 20 to a voltage.

In addition, the reset gate Grst of the reset transistor TR1rst is disposed next to the floating diffusion FD1. This allows the reset transistor TR1rst to reset carriers accumulated in the floating diffusion FD1.

The photoelectric conversion section 20 is coupled not only to the amplifier transistor TR1amp, but also to the floating diffusion FD1 via the through-electrode 34, thus enabling the reset transistor TR1rst to easily reset the carriers accumulated in the floating diffusion FD1.

In contrast, in a case where the through-electrode 34 and the floating diffusion FD1 are not coupled to each other, it is difficult to reset the carriers accumulated in the floating diffusion FD1, thus causing a large voltage to be applied to pull out the carriers to the side of the upper electrode 25. The photoelectric conversion layer 24 may therefore be possibly damaged. In addition, a structure that enables resetting in a short period of time leads to an increase in dark noises, resulting in a trade-off. This structure is thus difficult.

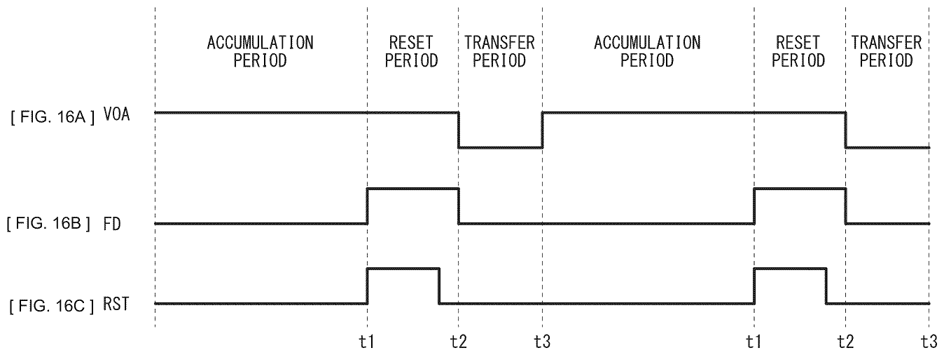

FIG. 16 illustrates an operation example of the imaging element 10. (A) illustrates the potential at the accumulation electrode 21B, (B) illustrates the potential at the floating diffusion FD1 (readout electrode 21A), and (C) illustrates the potential at the gate (Gsel) of the reset transistor TR1rst. In the imaging element 10, respective voltages are applied individually to the readout electrode 21A and the accumulation electrode 21B.

In the imaging element 10, the drive circuit applies a potential V1 to the readout electrode 21A and applies a potential V2 to the accumulation electrode 21B in an accumulation period. Here, it is assumed that the potentials V1 and V2 satisfy V2>V1. This allows carriers (signal charge: electrons) generated through photoelectric conversion to be drawn to the accumulation electrode 21B and to be accumulated in a region of the semiconductor layer 23 opposed to the accumulation electrode 21B (accumulation period). Incidentally, the value of the potential in the region of the semiconductor layer 23 opposed to the accumulation electrode 21B becomes more negative with the passage of time of photoelectric conversion. It is to be noted that holes are sent from the upper electrode 25 to the drive circuit.

In the imaging element 10, a reset operation is performed in the latter half of the accumulation period. Specifically, at a timing t1, a scanning section changes the voltage of a reset signal RST from a low level to a high level. This brings the reset transistor TR1rst into an ON state in the unit pixel P. As a result, the voltage of the floating diffusion FD1 is set to a power supply voltage, and the voltage of the floating diffusion FD1 is reset (reset period).

After the reset operation is completed, the carriers are read. Specifically, the drive circuit applies a potential V3 to the readout electrode 21A and applies a potential V4 to the accumulation electrode 21B at a timing t2. Here, it is assumed that the potentials V3 and V4 satisfy V3<V4. This allows the carriers accumulated in the region corresponding to the accumulation electrode 21B to be read from the readout electrode 21A to the floating diffusion FD1. That is, the carriers accumulated in the semiconductor layer 23 is read to the controller (transfer period).

The drive circuit applies the potential V1 to the readout electrode 21A and applies the potential V2 to the accumulation electrode 21B again after the readout operation is completed. This allows carriers generated through photoelectric conversion to be drawn to the accumulation electrode 21B and to be accumulated in the region of the photoelectric conversion layer 24 opposed to the accumulation electrode 21B (accumulation period).

### (Acquisition of Blue Color Signal and Red Color Signal by Photoelectric Conversion Regions 32B and 32R)

Subsequently, the blue light and the red light of the light beams having been transmitted through the photoelectric conversion section 20 are respectively absorbed and photoelectrically converted in order by the photoelectric conversion region 32B and the photoelectric conversion region 32R. In the photoelectric conversion region 32B, electrons corresponding to the incident blue light are accumulated in an n region of the photoelectric conversion region 32B, and the accumulated electrons are transferred to the floating diffusion FD2 by the transfer transistor Tr2. Likewise, in the photoelectric conversion region 32R, electrons corresponding to the incident red light are accumulated in an n region of the photoelectric conversion region 32R, and the accumulated electrons are transferred to the floating diffusion FD3 by the transfer transistor Tr3.

### (1-4. Workings and Effects)

The imaging element 10 according to the present embodiment includes the semiconductor layer 23 between the lower electrode 21 and the photoelectric conversion layer 24 in the photoelectric conversion section 20. The lower electrode 21 includes the readout electrode 21A and the accumulation electrode 21B. The semiconductor layer 23 includes the first layer 23A and the second layer 23B which are stacked in this order from the side of the lower electrode 11. The thickness of the first layer 23A is smaller than the thickness of the second layer 23B, and is set to 3 nm or more and 5 nm or less. This reduces the influence of fixed electric charge on the surface of the semiconductor layer 23 while maintaining carrier conduction in the semiconductor layer 23. This is described below.

In recent years, a stacked imaging element in which a plurality of photoelectric conversion sections is stacked in the vertical direction has been developed as an imaging element constituting a CCD image sensor, a CMOS image sensor, or the like. The stacked imaging element has a configuration in which two photoelectric conversion regions each including a photodiode (PD) are formed to be stacked, for example, in a silicon (Si) substrate and a photoelectric conversion section including a photoelectric conversion layer including an organic material is provided above the Si substrate.

The stacked imaging element is required to have a structure that accumulates and transfers signal charge generated by each of the photoelectric conversion sections. For example, among a pair of electrodes disposed to be opposed to each other with the photoelectric conversion layer interposed therebetween, the electrode on a side of the photoelectric conversion region is configured by two electrodes of a first electrode and a charge accumulation electrode in the organic photoelectric conversion section. This makes it possible to accumulate signal charge generated by the photoelectric conversion layer. Such an imaging element temporarily accumulates signal charge above the charge accumulation electrode, and then transfers the signal charge to the floating diffusion FD in the Si substrate. This makes it possible to fully deplete a charge accumulation section and erase carriers at the start of exposure. As a result, it is possible to suppress the occurrence of phenomena such as an increase in kTC noise, deterioration in random noise, and a decrease in image quality of a captured image.

Incidentally, an imaging element including a plurality of electrodes on the side of the photoelectric conversion region is provided with a composite oxide layer including indium-gallium-zinc composite oxide (IGZO) between the photoelectric conversion layer and the first electrode including the charge accumulation electrode, as described above. This achieves an improvement in photoresponsivity. The composite oxide layer has a two-layer structure, and is provided for the purpose of preventing stagnation of carriers from the photoelectric conversion layer to the composite oxide layer. However, the composite oxide layer is a cause of deterioration in reliability. It is presumed that the deterioration in reliability is caused by frequent oxygen defect in an oxide semiconductor layer (a lower layer) provided on a side of the first electrode and by fixed electric charge on a surface of the oxide semiconductor layer (an upper layer) provided on a side of the photoelectric conversion layer.

In contrast, in the present embodiment, the semiconductor layer 23 is provided between the lower electrode 21 and the photoelectric conversion layer 24. The lower electrode 21 includes the readout electrode 21A and the accumulation electrode 21B. The semiconductor layer 23 includes the first layer 23A and the second layer 23B which are stacked in this order from the side of the lower electrode 11. The thickness of the first layer 23A is smaller than the thickness of the second layer 23B, and is set to 3 nm or more and 5 nm or less. This reduces the oxygen defect in the first layer 23A, thus making it possible to maintain the carrier conduction in the semiconductor layer 23. In addition, allowing the second layer 23B to have a thicker film than the first layer 23A (setting the ratio (t1/t2) between the thickness (t1) of the first layer 23A and the thickness (t2) of the second layer 23B to 0.16 or less) reduces the influence of fixed electric charge on the surface of the semiconductor layer 23, thus decreasing the variation amount of the threshold voltage (Vth).

As described above, it is possible for the imaging element 10 of the present embodiment to improve the reliability.

Next, description is given of modification examples (Modification Examples 1 to 5) of the present disclosure. Hereinafter, components similar to those of the foregoing embodiment are denoted by the same reference numerals, and descriptions thereof are omitted as appropriate.

### 2. Modification Examples

### 2-1. Modification Example 1

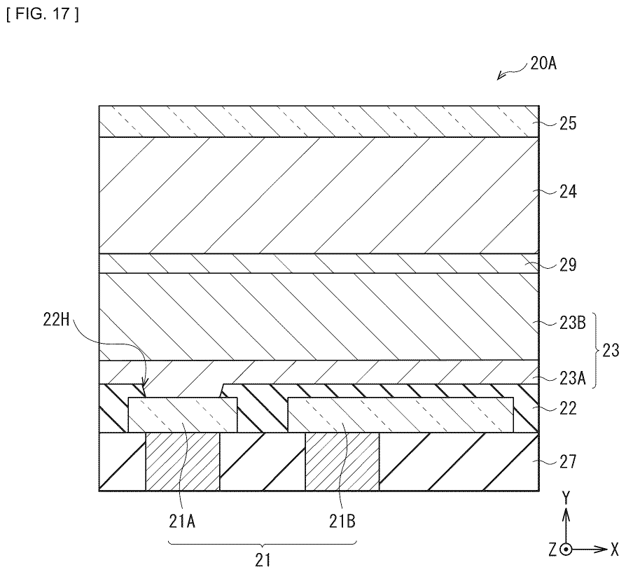

FIG. 17 schematically illustrates a cross-sectional configuration of a main part (a photoelectric conversion section 20A) of an imaging element according to Modification Example 1 of the present disclosure. The photoelectric conversion section 20A according to the present modification example differs from that of the foregoing embodiment in that a protective layer 29 is provided between the semiconductor layer 23 and the photoelectric conversion layer 24.

The protective layer 29 is provided to prevent desorption of oxygen from the oxide semiconductor material constituting the semiconductor layer 23. Examples of a material constituting the protective layer 29 include TiO₂, titanium silicide oxide (TiSiO), niobium oxide (Nb₂O₅), TaOₓ, and the like. For example, one atomic layer is effective for the thickness of the protective layer 29. The protective layer 29 preferably has a thickness of 0.5 nm or more and 10 nm or less, for example.

In this manner, in the present modification example, the protective layer 29 is provided between the semiconductor layer 23 and the photoelectric conversion layer 24. This makes it possible to reduce the desorption of oxygen from the surface of the semiconductor layer 23. This reduces generation of a trap at the interface between the semiconductor layer 23 (specifically, the second layer 23B) and the photoelectric conversion layer 24. In addition, it becomes possible to prevent signal charge (electrons) from flowing back to the photoelectric conversion layer 24 from a side of the semiconductor layer 23. This achieves an effect of enabling suppression of a decrease in the reliability caused by the desorption of oxygen, in addition to the effects of the foregoing embodiment.

### 2-2. Modification Example 2

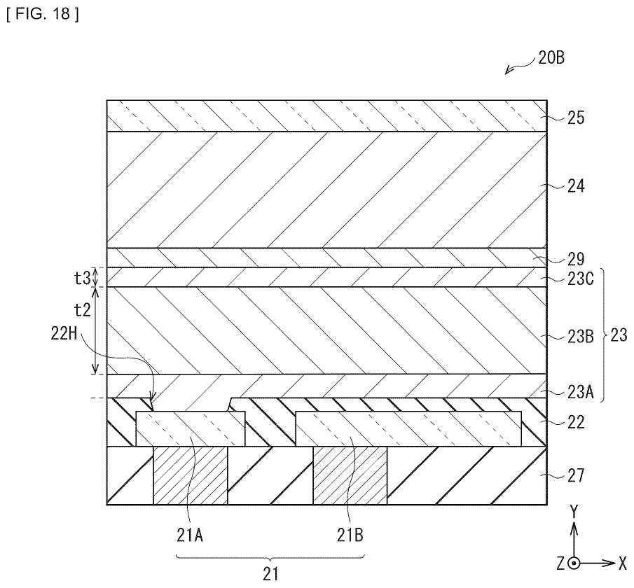

FIG. 18 schematically illustrates a cross-sectional configuration of a main part (a photoelectric conversion section 20B) of an imaging element according to Modification Example 2 of the present disclosure. The photoelectric conversion section 20B according to the present modification example further includes a third layer 23C on the second layer 23B, in addition to the components of the photoelectric conversion section 20A according to the foregoing Modification Example 1.

In the semiconductor layer 23 according to the present modification example, the first layer 23A, the second layer 23B, and the third layer 23C are stacked in this order from the side of the lower electrode 21. The first layer 23A and the second layer 23B have configurations similar to those of the foregoing embodiment.

The third layer 23C is provided to suppress oxygen deficiency in the semiconductor layer 23, and has an amorphous property. In the same manner as the first layer 23A and the second layer 23B, the third layer 23C may be formed using an indium oxide semiconductor. Specific examples thereof include IGZO and IGO. Bonding of zinc (Zn) to oxygen (O) is weaker than that of indium (In), and thus formation of the third layer 23C using IGO containing no Zn makes it possible to suppress the oxygen deficiency in the semiconductor layer 23. The third layer 23C has a thickness of 1 nm or more and 10 nm or less, for example. The third layer 23C corresponds to a specific example of a “third layer” of the present disclosure.

In this manner, in the present modification example, the semiconductor layer 23 has a three-layer structure of the first layer 23A, the second layer 23B, and the third layer 23C. Further, the protective layer 29 is provided between the semiconductor layer 23 and the photoelectric conversion layer 24. This makes it possible to further prevent the desorption of oxygen from the surface of the semiconductor layer 23 (specifically, the third layer 23C) and thus to further improve the reliability.

Further, the present technology is also applicable to an imaging element having the following configurations.

### 2-3. Modification Example 3

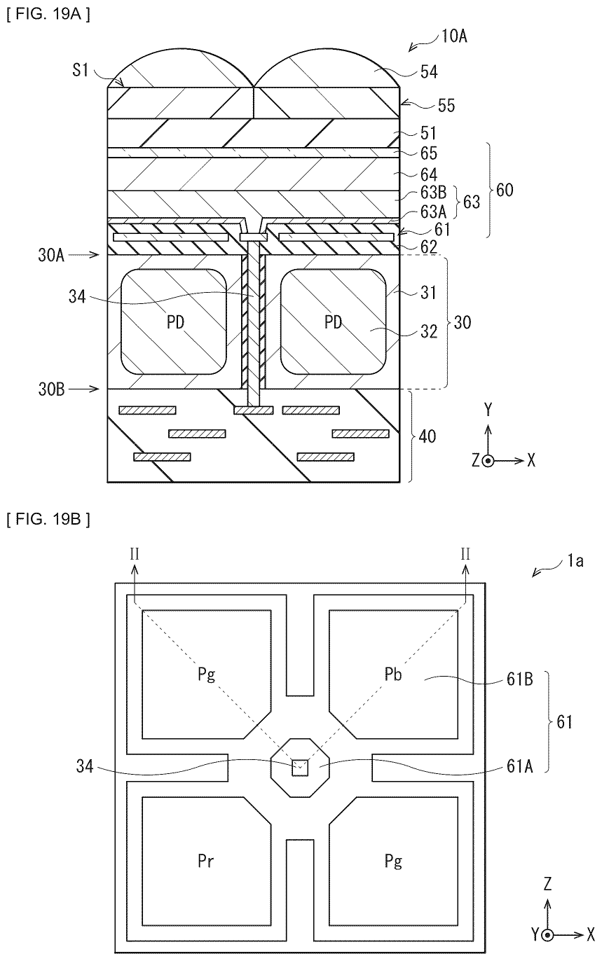

FIG. 19A schematically illustrates a cross-sectional configuration of an imaging element 10A according to Modification Example 3 of the present disclosure. FIG. 19B schematically illustrates an example of a planar configuration of the imaging element 10A illustrated in FIG. 19A. FIG. 19A illustrates a cross-section taken along a line III-III illustrated in FIG. 19B. The imaging element 10A is a stacked imaging element in which, for example, a photoelectric conversion region 32 and an organic photoelectric conversion section 60 are stacked. In the pixel section 1A of an imaging device (e.g., the imaging device 1) including this imaging element 10A, the pixel unit 1a including four pixels arranged in two rows×two columns serves as a repeating unit, and is repeatedly arranged in an array including the row direction and the column direction.

The imaging element 10A according to the present modification example is provided with color filters 55 above the photoelectric conversion sections 60 (light incident side S1) for the respective unit pixels P. The respective color filters 55 selectively transmit red light (R), green light (G), and blue light (B). Specifically, in the pixel unit 1a including four pixels arranged in two rows×two columns, two color filters each of which selectively transmits green light (G) are arranged on a diagonal line, and color filters that selectively transmit red light (R) and blue light (B) are arranged one by one on orthogonal diagonal lines. The unit pixels (Pr, Pg, and Pb) provided with the respective color filters each detect corresponding color light, for example, in the photoelectric conversion section 60. That is, the respective pixels (Pr, Pg, and Pb) that detect red light (R), green light (G), and blue light (B) are arranged in a Bayer arrangement in the pixel section 1A.

The photoelectric conversion section 60 includes, for example, a lower electrode 61, an insulating layer 62, a semiconductor layer 63, a photoelectric conversion layer 64, and an upper electrode 65. The lower electrode 61, the insulating layer 62, the semiconductor layer 63, the photoelectric conversion layer 64, and the upper electrode 65 each have a configuration similar to that of the photoelectric conversion section 20 according to the foregoing embodiment. The photoelectric conversion region 32 detects light in a wavelength region different from that of the photoelectric conversion section 60.

In the imaging element 10A, light beams (red light (R), green light (G), and blue light (B)) in a visible light region among the light beams transmitted through the color filters 55 are absorbed by the photoelectric conversion sections 60 of the unit pixels (Pr, Pg, and Pb) provided with the respective color filters. Another light, e.g., light (infrared light (IR)) in an infrared light region (e.g., 700 nm or more and 1000 nm or less) is transmitted through the photoelectric conversion sections 60. The infrared light (IR) transmitted through the photoelectric conversion section 60 is detected by the photoelectric conversion region 32 of each of the unit pixels Pr, Pg, and Pb. Each of the unit pixels Pr, Pg, and Pb generates signal charge corresponding to the infrared light (IR). That is, the imaging device 1 including the imaging element 10A is able to concurrently generate both a visible light image and an infrared light image.

### 2-4. Modification Example 4

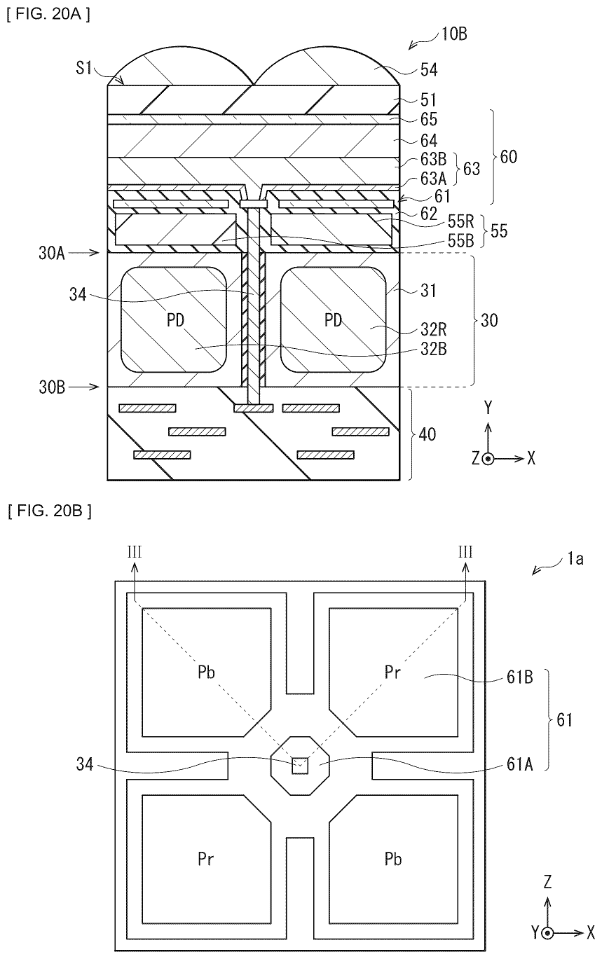

FIG. 20A schematically illustrates a cross-sectional configuration of an imaging element 10B according to Modification Example 4 of the present disclosure. FIG. 20B schematically illustrates an example of a planar configuration of the imaging element 10B illustrated in FIG. 20A. FIG. 20A illustrates a cross-section taken along a line IV-IV illustrated in FIG. 20B. In Modification Example 7 described above, the example has been described in which the color filters 55 that selectively transmit red light (R), green light (G), and blue light (B) are provided above the photoelectric conversion sections 60 (light incident side S1), but the color filters 55 may be each provided between the photoelectric conversion region 32 and the photoelectric conversion section 60, for example, as illustrated in FIG. 20A.

For example, the imaging element 10B has a configuration in which color filters (color filters 55R) each of which selectively transmits at least red light (R) and color filters (color filters 55B) each of which selectively transmits at least blue light (B) are arranged on the respective diagonal lines in the pixel unit 1a. The photoelectric conversion section 60 (photoelectric conversion layer 64) is configured to selectively absorb a wavelength corresponding to green light, for example, in the same manner as the foregoing embodiment. This enables the photoelectric conversion sections 60 and the respective photoelectric conversion regions (photoelectric conversion regions 32R and 32G) arranged below the color filters 55R and 55B to acquire signals corresponding to R, G, and B. The imaging element 10B according to the present modification example enables the respective photoelectric conversion sections of R, G, and B to each have a larger area than that of the imaging element having a typical Bayer arrangement. This makes it possible to improve the S/N ratio.

### 2-5. Modification Example 5

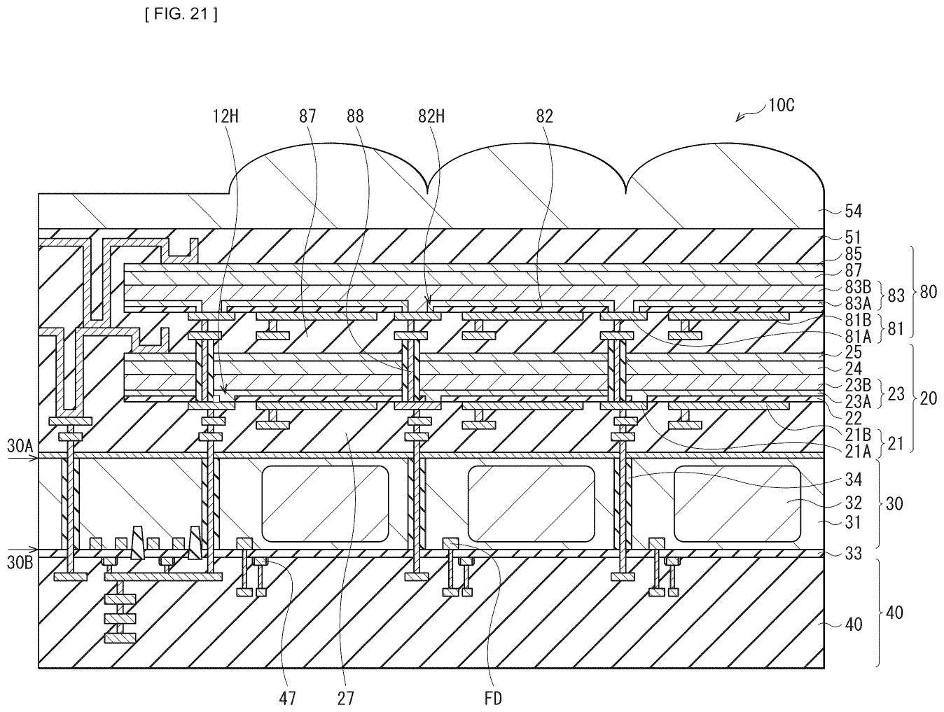

FIG. 21 schematically illustrates a cross-sectional configuration of an imaging element 10C according to Modification Example 5 of the present disclosure. In the imaging element 10C of the present modification example, two photoelectric conversion sections 20 and 80 and one photoelectric conversion region 32 are stacked in the vertical direction.

The photoelectric conversion sections 20 and 80 and the photoelectric conversion region 32 selectively detect light beams in wavelength regions different from each other to perform photoelectric conversion. For example, the photoelectric conversion section 20 acquires a color signal of green (G). For example, the photoelectric conversion section 80 acquires a color signal of blue (B). For example, the photoelectric conversion region 32 acquires a color signal of red (R). This enables the imaging element 10C to acquire a plurality of types of color signals in one pixel without using a color filter.

The photoelectric conversion section 80 is stacked, for example, above the photoelectric conversion section 20. In the same manner as the photoelectric conversion section 20, the photoelectric conversion section 80 has a configuration in which a lower electrode 81, a semiconductor layer 83, a photoelectric conversion layer 84, and an upper electrode 85 are stacked in this order from the side of the first surface 30A of the semiconductor substrate 30. The semiconductor layer 83 includes, for example, a first semiconductor layer 83A and a second semiconductor layer 83B. In the same manner as the photoelectric conversion section 20, the lower electrode 81 is configured by a readout electrode 81A and an accumulation electrode 81B. The lower electrode 81 is electrically separated by an insulating layer 82. The insulating layer 82 is provided with an opening 82H on the readout electrode 81A. An interlayer insulating layer 87 is provided between the photoelectric conversion section 80 and the photoelectric conversion section 20.

A through-electrode 88 is coupled to the readout electrode 81A. The through-electrode 88 penetrates the interlayer insulating layer 87 and the photoelectric conversion section 20, and is electrically coupled to the readout electrode 21A of the photoelectric conversion section 20. Further, the readout electrode 81A is electrically coupled to the floating diffusion FD provided in the semiconductor substrate 30 via the through-electrodes 34 and 88, thus enabling carriers generated in the photoelectric conversion layer 84 to be temporarily accumulated. Further, the readout electrode 81A is electrically coupled to the amplifier transistor AMP or the like provided in the semiconductor substrate 30 via the through-electrodes 34 and 88.

### 3. Application Examples

### Application Example 1

FIG. 22 illustrates an example of an overall configuration of an imaging device (imaging device 1) including the imaging element (e.g., imaging element 10) illustrated in FIG. 1 or other drawings.

The imaging device 1 is, for example, a CMOS image sensor. The imaging device 1 takes in incident light (image light) from a subject via an optical lens system (unillustrated), and converts the amount of incident light formed as an image on an imaging surface into electric signals in units of pixels to output the electric signals as pixel signals. The imaging device 1 includes the pixel section 1A as an imaging area on the semiconductor substrate 30. In addition, the imaging device 1 includes, for example, a vertical drive circuit 111, the column signal processing circuit 112, a horizontal drive circuit 113, an output circuit 114, a control circuit 115, and an input/output terminal 116 in a peripheral region of this pixel section 1A.

The pixel section 1A includes, for example, the plurality of unit pixels P that are two-dimensionally arranged in matrix. The unit pixels P are provided, for example, with a pixel drive line Lread (specifically, a row selection line and a reset control line) for each of pixel rows and provided with a vertical signal line Lsig for each of pixel columns. The pixel drive line Lread transmits drive signals for reading signals from the pixels. One end of the pixel drive line Lread is coupled to an output end of the vertical drive circuit 111 corresponding to each of the rows.

The vertical drive circuit 111 is a pixel drive section that is configured by a shift register, an address decoder, and the like and drives the unit pixels P of the pixel section 1A on a row-by-row basis, for example. Signals outputted from the respective unit pixels P in the pixel rows selectively scanned by the vertical drive circuit 111 are supplied to the column signal processing circuit 112 through the respective vertical signal lines Lsig. The column signal processing circuit 112 is configured by an amplifier, a horizontal selection switch, and the like provided for each of the vertical signal lines Lsig.

The horizontal drive circuit 113 is configured by a shift register, an address decoder, and the like. The horizontal drive circuit 113 drives horizontal selection switches of the column signal processing circuit 112 in order while scanning the horizontal selection switches. The selective scanning by this horizontal drive circuit 113 causes signals of the respective pixels transmitted through the respective vertical signal lines Lsig to be outputted to a horizontal signal line 121 in order and causes the signals to be transmitted to the outside of the semiconductor substrate 30 through the horizontal signal line 121.

The output circuit 114 performs signal processing on signals sequentially supplied from the respective column signal processing circuits 112 via the horizontal signal line 121, and outputs the signals. The output circuit 114 performs, for example, only buffering in some cases, and performs black level adjustment, column variation correction, various kinds of digital signal processing, and the like in other cases.

The circuit portion including the vertical drive circuit 111, the column signal processing circuit 112, the horizontal drive circuit 113, the horizontal signal line 121, and the output circuit 114 may be formed directly on the semiconductor substrate 30, or may be provided on an external control IC. In addition, the circuit portion may be formed in another substrate coupled by a cable or the like.

The control circuit 115 receives a clock supplied from the outside of the semiconductor substrate 30, data for an instruction about an operation mode, and the like and also outputs data such as internal information on the imaging device 1. The control circuit 115 further includes a timing generator that generates various timing signals, and controls driving of the peripheral circuits including the vertical drive circuit 111, the column signal processing circuit 112, the horizontal drive circuit 113, and the like on the basis of the various timing signals generated by the timing generator.

The input/output terminal 116 exchanges signals with the outside.

### Application Example 2

In addition, the above-described imaging device 1 is applicable, for example, to various types of electronic apparatuses including an imaging system such as a digital still camera and a video camera, a mobile phone having an imaging function, or another device having an imaging function.

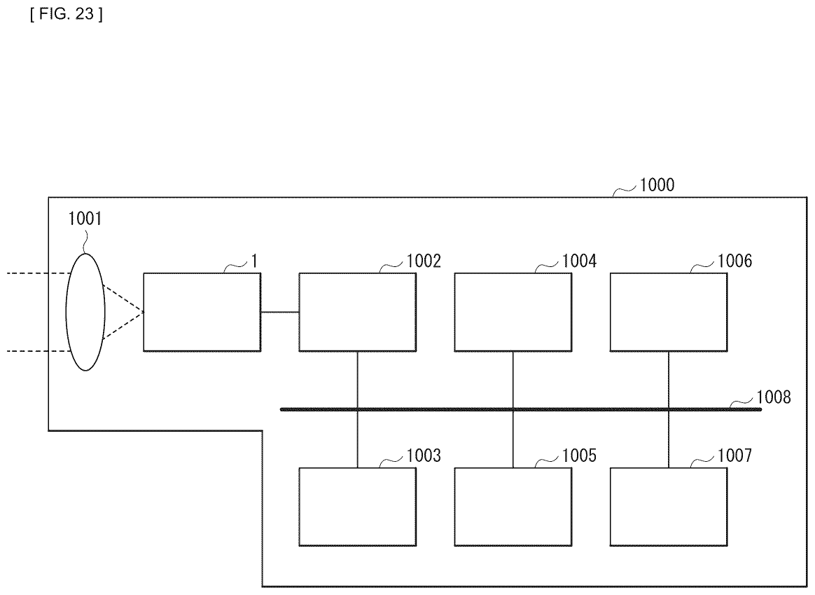

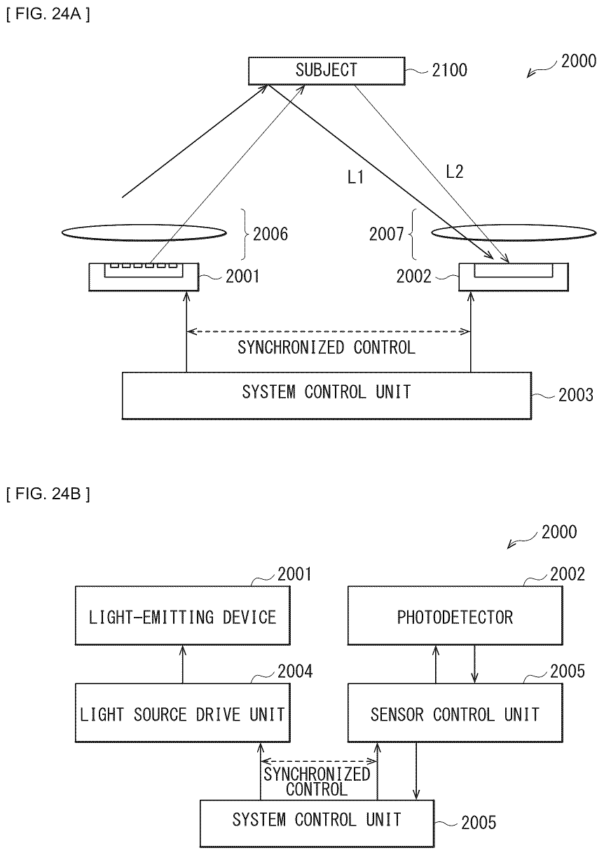

FIG. 23 is a block diagram illustrating an example of a configuration of an electronic apparatus 1000.

As illustrated in FIG. 23, the electronic apparatus 1000 includes an optical system 1001, the imaging device 1, and a DSP (Digital Signal Processor) 1002, and has a configuration in which the DSP 1002, a memory 1003, a display device 1004, a recording device 1005, an operation system 1006, and a power supply system 1007 are coupled together via a bus 1008, thus making it possible to capture a still image and a moving image.

The optical system 1001 includes one or a plurality of lenses, and takes in incident light (image light) from a subject to form an image on an imaging surface of the imaging device 1.

The above-described imaging device 1 is applied as the imaging device 1. The imaging device 1 converts the amount of incident light formed as an image on the imaging surface by the optical system 1001 into electric signals in units of pixels, and supplies the DSP 1002 with the electric signals as pixel signals.

The DSP 1002 performs various types of signal processing on the signals from the imaging device 1 to acquire an image, and causes the memory 1003 to temporarily store data on the image. The image data stored in the memory 1003 is recorded in the recording device 1005, or is supplied to the display device 1004 to display the image. In addition, the operation system 1006 receives various operations by the user, and supplies operation signals to the respective blocks of the electronic apparatus 1000. The power supply system 1007 supplies electric power required to drive the respective blocks of the electronic apparatus 1000.

### Application Example 3

FIG. 24A schematically illustrates an example of an overall configuration of a photodetection system 2000 including the imaging device 1. FIG. 24B illustrates an example of a circuit configuration of the photodetection system 2000. The photodetection system 2000 includes a light-emitting device 2001 as a light source unit that emits infrared light L2 and a photodetector 2002 as a light-receiving unit with a photoelectric conversion element. The above-described imaging device 1 may be used as the photodetector 2002. The photodetection system 2000 may further include a system control unit 2003, a light source drive unit 2004, a sensor control unit 2005, a light source side optical system 2006, and a camera side optical system 2007.

The photodetector 2002 is able to detect light L1 and light L2. The light L1 is reflected light of ambient light from the outside reflected by a subject (measurement target) 2100 (FIG. 24A). The light L2 is light reflected by the subject 2100 after having been emitted by the light-emitting device 2001. The light L1 is, for example, visible light, and the light L2 is, for example, infrared light. The light L1 is detectable at the photoelectric conversion section in the photodetector 2002, and the light L2 is detectable at a photoelectric conversion region in the photodetector 2002. It is possible to acquire image information on the subject 2100 from the light L1 and to acquire information on a distance between the subject 2100 and the photodetection system 2000 from the light L2. For example, the photodetection system 2000 can be mounted on an electronic apparatus such as a smartphone or on a mobile body such as a car. The light-emitting device 2001 can be configured by, for example, a semiconductor laser, a surface-emitting semiconductor laser, or a vertical resonator surface-emitting laser (VCSEL). An iTOF method can be employed as a method for the photodetector 2002 to detect the light L2 emitted from the light-emitting device 2001; however, this is not limitative. In the iTOF method, the photoelectric conversion section is able to measure a distance to the subject 2100 by time of flight of light (Time-of-Flight; TOF), for example. As a method for the photodetector 2002 to detect the light L2 emitted from the light-emitting device 2001, it is possible to adopt, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to acquire two or more images of the subject 2100 viewed from two or more different viewpoints, thereby making it possible to measure the distance between the photodetection system 2000 and the subject. It is to be noted that it is possible for the system control unit 2003 to synchronously control the light-emitting device 2001 and the photodetector 2002.

### 4. Practical Application Examples

### (Example of Practical Application to Endoscopic Surgery System)

The technology according to an embodiment of the present disclosure (present technology) is applicable to various products. For example, the technology according to an embodiment of the present disclosure may be applied to an endoscopic surgery system.

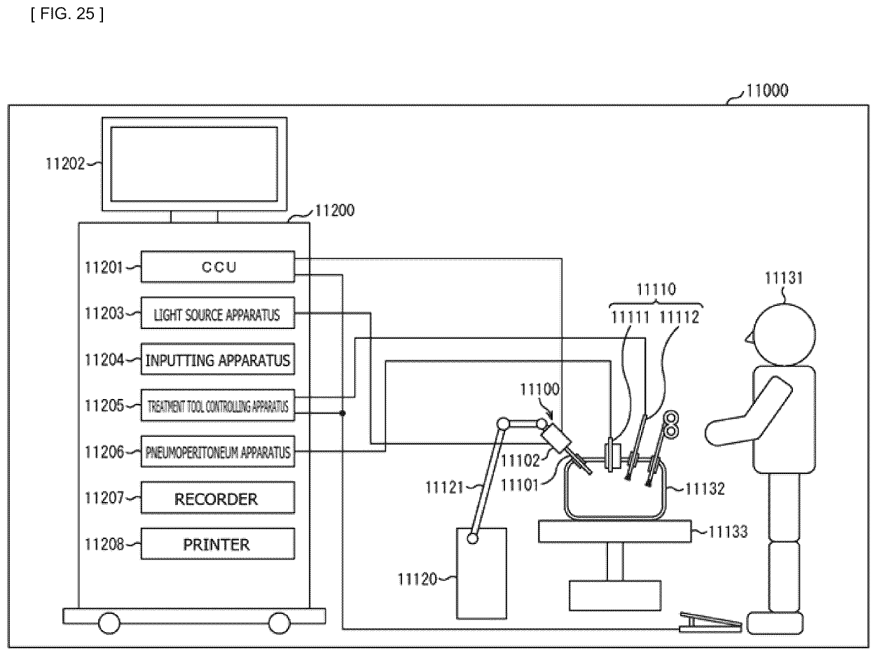

FIG. 25 is a view depicting an example of a schematic configuration of an endoscopic surgery system to which the technology according to an embodiment of the present disclosure (present technology) can be applied.

In FIG. 25, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength region ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

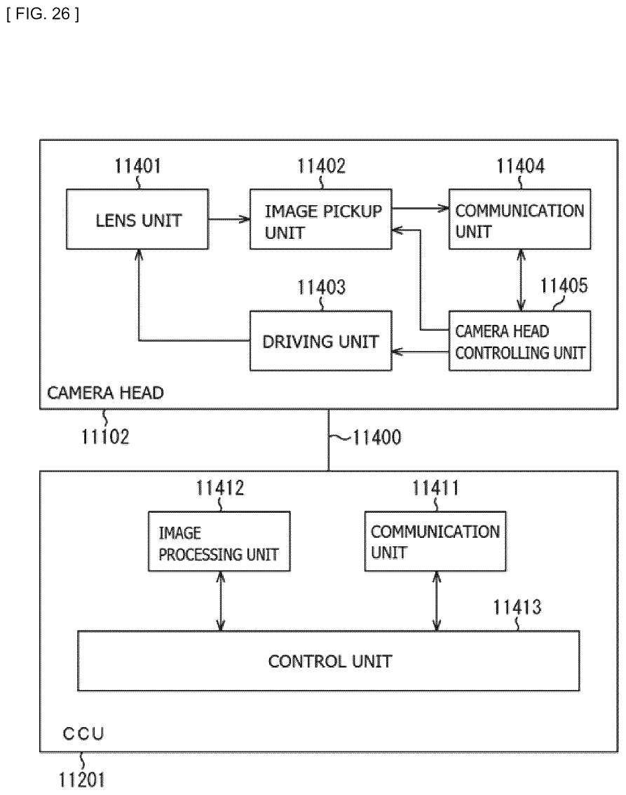

FIG. 26 is a block diagram depicting an example of a functional configuration of the camera head 11102 and the CCU 11201 depicted in FIG. 25.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the configurations described above. Applying the technology according to an embodiment of the present disclosure to the image pickup unit 11402 makes it possible to improve detection accuracy.

It is to be noted that although the endoscopic surgery system has been described as an example here, the technology according to an embodiment of the present disclosure may also be applied to, for example, a microscopic surgery system, and the like.

### (Example of Practical Application to Mobile Body)

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, a robot, a construction machine, and an agricultural machine (tractor).

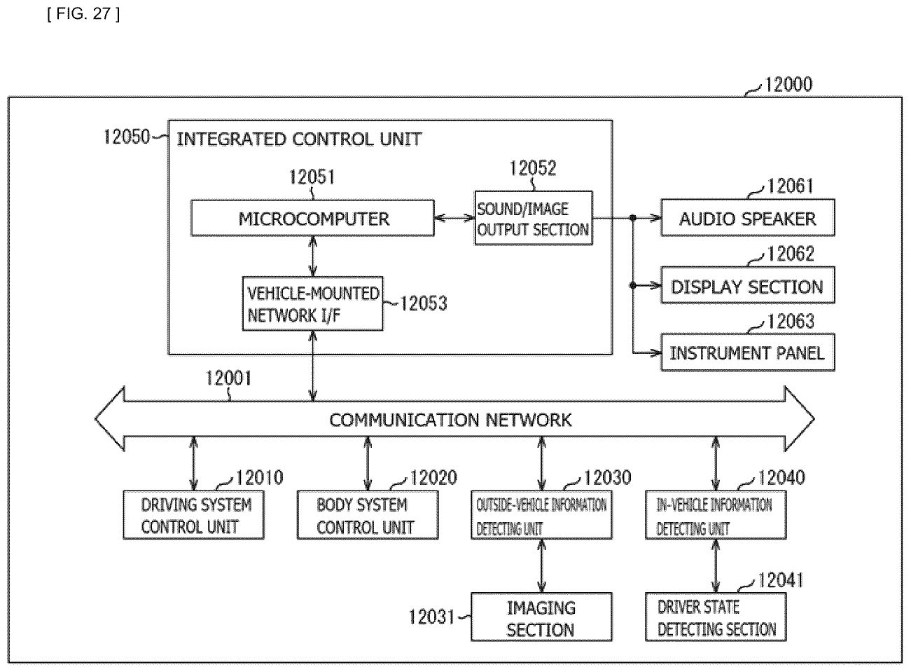

FIG. 27 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 27, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 27, an audio speaker 12061, a display section 12062, and an instrument panel 12063 are illustrated as the output device. The display section 12062 may, for example, include at least one of an on-board display and a head-up display.

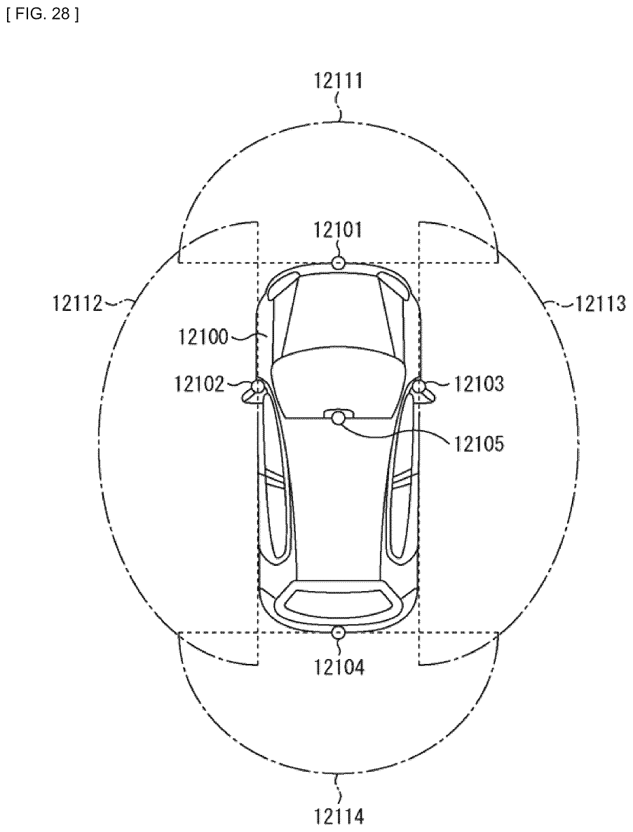

FIG. 28 is a diagram depicting an example of the installation position of the imaging section 12031.

In FIG. 28, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 28 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

Description has been given hereinabove by referring to the embodiment and Modification Examples 1 to 5 as well as the application examples and the practical application examples; however, the content of the present disclosure is not limited to the foregoing embodiment and the like, and may be modified in a wide variety of ways. For example, in the foregoing embodiment, the imaging element has a configuration in which the photoelectric conversion section 20 that detects green light and the photoelectric conversion regions 32B and 32R that detect, respectively, blue light and red light are stacked. However, the content of the present disclosure is not limited to such a structure. For example, red light or blue light may be detected in the photoelectric conversion section, or green light may be detected in the photoelectric conversion region.

Further, the numbers of the photoelectric conversion section and the photoelectric conversion region, and the ratio therebetween are not limitative. Two or more photoelectric conversion sections may be provided, or only a photoelectric conversion section may be used to obtain color signals of a plurality of colors.

Further, the foregoing embodiment and the like exemplify the configuration of the two electrodes of the readout electrode 21A and the accumulation electrode 21B, as the plurality of electrodes constituting the lower electrode 21. However, in addition thereto, three or more electrodes such as a transfer electrode and a discharge electrode may be provided.

It is to be noted that the effects described herein are merely exemplary and are not limitative, and may further include other effects.

It is to be noted that the present technology may also have the following configurations. According to the present technology of the following configurations, a semiconductor layer including a first layer and a second layer stacked in order from a side of a first electrode and a second electrode disposed side by side with each other, in which the first layer has a thickness that is smaller than a thickness of the second layer and that is 3 nm or more and 5 nm or less, is provided between the first electrode and the photoelectric conversion layer and between the second electrode and the photoelectric conversion layer. This reduces the influence of fixed electric charge on a surface of the semiconductor layer while maintaining carrier conduction in the semiconductor layer. It is therefore possible to improve the reliability.

(1)

A photoelectric conversion element including:
a first electrode and a second electrode disposed side by side with each other;
a third electrode disposed to be opposed to the first electrode and the second electrode;
a photoelectric conversion layer provided between the first electrode and the third electrode and between the second electrode and the third electrode; and
a semiconductor layer provided between the first electrode and the photoelectric conversion layer and between the second electrode and the photoelectric conversion layer, the semiconductor layer including a first layer and a second layer stacked in order from a side of the first electrode and the second electrode, the first layer having a thickness smaller than a thickness of the second layer, the thickness of the first layer being 3 nm or more and 5 nm or less.
   (2)

The photoelectric conversion element according to (1), in which a ratio (t1/t2) between a film thickness (t1) of the first layer and a film thickness (t2) of the second layer is 0.16 or less.

(3)

The photoelectric conversion element according to (1) or (2), in which the first layer and the second layer are each formed using indium oxide, and a content ratio of indium contained in a first indium oxide constituting the first layer is higher than a content ratio of indium contained in a second indium oxide constituting the second layer.

(4)

The photoelectric conversion element according to any one of (1) to (3), in which the second layer has a film thickness of 32 nm or more.

(5)

The photoelectric conversion element according to any one of (1) to (4), in which the first layer and the second layer each have a crystalline property.

(6)

The photoelectric conversion element according to any one of (1) to (4), in which the first layer and the second layer each have an amorphous property.

(7)

The photoelectric conversion element according to any one of (1) to (6), in which the semiconductor layer further includes, between the photoelectric conversion layer and the second layer, a third layer having an amorphous property.

(8)

The photoelectric conversion element according to (7), in which the third layer has a film thickness of 1 nm or more and 10 nm or less.

(9)

The photoelectric conversion element according to any one of (1) to (8), further including an insulating layer provided between the first electrode and the semiconductor layer and between the second electrode and the semiconductor layer, the insulating layer having an opening above the first electrode, and
the second electrode and the semiconductor layer are electrically coupled to each other via the opening.
   (10)

The photoelectric conversion element according to any one of (1) to (9), further including, between the photoelectric conversion layer and the semiconductor layer, a protective layer that includes an inorganic material.

(11)

The photoelectric conversion element according to any one of (1) to (10), in which the first electrode and the second electrode are disposed on a side opposite to a light incident surface with respect to the photoelectric conversion layer.

(12)

The photoelectric conversion element according to any one of (1) to (11), in which respective voltages are applied individually to the first electrode and the second electrode.

(13)

A photodetector including a plurality of pixels each including one or a plurality of photoelectric conversion elements,
the photoelectric conversion element including
   a first electrode and a second electrode disposed side by side with each other,
   a third electrode disposed to be opposed to the first electrode and the second electrode,
   a photoelectric conversion layer provided between the first electrode and the third electrode and between the second electrode and the third electrode, and
   a semiconductor layer provided between the first electrode and the photoelectric conversion layer and between the second electrode and the photoelectric conversion layer, the semiconductor layer including a first layer and a second layer stacked in order from a side of the first electrode and the second electrode, the first layer having a thickness smaller than a thickness of the second layer, the thickness of the first layer being 3 nm or more and 5 nm or less.
      (14)

The photodetector according to (13), in which the photoelectric conversion element further includes one or a plurality of photoelectric conversion regions that performs photoelectric conversion of a wavelength region different from the one or the plurality of photoelectric conversion elements.

(15)

The photodetector according to (14), in which
the one or the plurality of photoelectric conversion regions is formed to be embedded in a semiconductor substrate, and
the one or the plurality of photoelectric conversion sections is disposed on a side of a light incident surface of the semiconductor substrate.
   (16)

The photodetector according to (15), in which a multilayer wiring layer is formed on a surface of the semiconductor substrate on a side opposite to the light incident surface.

(17)

A photoelectric conversion element including:
a first electrode and a second electrode disposed side by side with each other;
a third electrode disposed to be opposed to the first electrode and the second electrode;
a photoelectric conversion layer provided between the first electrode and the third electrode and between the second electrode and the third electrode; and
a semiconductor layer provided between the first electrode and the photoelectric conversion layer and between the second electrode and the photoelectric conversion layer, the semiconductor layer including a first layer and a second layer stacked in order from a side of the first electrode and the second electrode, in which a ratio (t1/t2) between a film thickness (t1) of the first layer and a film thickness (t2) of the second layer is 0.16 or less.

The present application claims the benefit of Japanese Priority Patent Application JP2022-039791 filed with the Japan Patent Office on Mar. 15, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photoelectric conversion element comprising:
a first electrode and a second electrode disposed side by side with each other;
a third electrode disposed to be opposed to the first electrode and the second electrode;
a photoelectric conversion layer provided between the first electrode and the third electrode and between the second electrode and the third electrode; and
a semiconductor layer provided between the first electrode and the photoelectric conversion layer and between the second electrode and the photoelectric conversion layer, the semiconductor layer including a first layer and a second layer stacked in order from a side of the first electrode and the second electrode, the first layer having a thickness smaller than a thickness of the second layer, the thickness of the first layer being 3 nm or more and 5 nm or less.

2. The photoelectric conversion element according to claim 1, wherein a ratio (t1/t2) between a film thickness (t1) of the first layer and a film thickness (t2) of the second layer is 0.16 or less.

3. The photoelectric conversion element according to claim 1, wherein
the first layer and the second layer are each formed using indium oxide, and
a content ratio of indium contained in a first indium oxide constituting the first layer is higher than a content ratio of indium contained in a second indium oxide constituting the second layer.

4. The photoelectric conversion element according to claim 1, wherein the second layer has a film thickness of 32 nm or more.

5. The photoelectric conversion element according to claim 1, wherein the first layer and the second layer each have a crystalline property.

6. The photoelectric conversion element according to claim 1, wherein the first layer and the second layer each have an amorphous property.

7. The photoelectric conversion element according to claim 1, wherein the semiconductor layer further includes, between the photoelectric conversion layer and the second layer, a third layer having an amorphous property.

8. The photoelectric conversion element according to claim 7, wherein the third layer has a film thickness of 1 nm or more and 10 nm or less.

9. The photoelectric conversion element according to claim 1, further comprising an insulating layer provided between the first electrode and the semiconductor layer and between the second electrode and the semiconductor layer, the insulating layer having an opening above the first electrode, and
the second electrode and the semiconductor layer are electrically coupled to each other via the opening.

10. The photoelectric conversion element according to claim 1, further comprising, between the photoelectric conversion layer and the semiconductor layer, a protective layer that includes an inorganic material.

11. The photoelectric conversion element according to claim 1, wherein the first electrode and the second electrode are disposed on a side opposite to a light incident surface with respect to the photoelectric conversion layer.

12. The photoelectric conversion element according to claim 1, wherein respective voltages are applied individually to the first electrode and the second electrode.

13. A photodetector comprising a plurality of pixels each including one or a plurality of photoelectric conversion elements,
the photoelectric conversion element including
a first electrode and a second electrode disposed side by side with each other,
a third electrode disposed to be opposed to the first electrode and the second electrode,
a photoelectric conversion layer provided between the first electrode and the third electrode and between the second electrode and the third electrode, and
a semiconductor layer provided between the first electrode and the photoelectric conversion layer and between the second electrode and the photoelectric conversion layer, the semiconductor layer including a first layer and a second layer stacked in order from a side of the first electrode and the second electrode, the first layer having a thickness smaller than a thickness of the second layer, the thickness of the first layer being 3 nm or more and 5 nm or less.

14. The photodetector according to claim 13, wherein the photoelectric conversion element further includes one or a plurality of photoelectric conversion regions that performs photoelectric conversion of a wavelength region different from the one or the plurality of photoelectric conversion elements.

15. The photodetector according to claim 14, wherein
the one or the plurality of photoelectric conversion regions is formed to be embedded in a semiconductor substrate, and
the one or the plurality of photoelectric conversion sections is disposed on a side of a light incident surface of the semiconductor substrate.

16. The photodetector according to claim 15, wherein a multilayer wiring layer is formed on a surface of the semiconductor substrate on a side opposite to the light incident surface.
